(19) United States
(12) Patent Application Publication
(10) Pub. No.: US 2025/0254921 A1
(43) Pub. Date: Aug. 7, 2025

(54) SEMICONDUCTOR STRUCTURE WITH AIR GAP AND METHOD FOR MANUFACTURING THE SAME

(71) Applicant: Taiwan Semiconductor Manufacturing Company, Ltd., Hsinchu (TW)

(72) Inventors: Tsung-Han CHUANG, Tainan City (TW); Jung-Hung CHANG, Changhua County (TW); Shih-Cheng CHEN, New Taipei City (TW); Chien-Ning YAO, Hsinchu (TW); Chia-Cheng TSAI, Hsinchu (TW); Kuo-Cheng CHIANG, Zhubei City (TW); Chih-Hao WANG, Baoshan Township (TW)

(73) Assignee: Taiwan Semiconductor Manufacturing Company, Ltd., Hsinchu (TW)

(21) Appl. No.: 18/733,180

(22) Filed: Jun. 4, 2024

Related U.S. Application Data
(60) Provisional application No. 63/550,322, filed on Feb. 6, 2024.

(51) Int. Cl. H01L 29/423; H01L 21/764; H01L 29/06; H01L 29/66; H01L 29/786

(52) U.S. Cl. CPC H10D 30/6735; H01L 21/764; H10D 30/6713; H10D 30/6757; H10D 62/121; H10D 64/015; H10D 64/018; H10D 64/021

(57) ABSTRACT

Semiconductor structures and method for forming the same are provided. The semiconductor structure includes channel structures vertically separated from each other and a gate structure wrapping around the channel structures. The semiconductor structure further includes a first porous layer formed over a first sidewall of the gate structure under the channel structures and a source/drain structure attached to the channel structures. In addition, the source/drain structure is laterally separated from the first porous layer by a first air gap.

### PRIORITY CLAIM AND CROSS-REFERENCE

This application claims priority to U.S. Provisional Application Ser. No. 63/550,332, filed on Feb. 6, 2024, the entirety of which is incorporated by reference herein.

### BACKGROUND

The electronics industry is experiencing ever-increasing demand for smaller and faster electronic devices that are able to perform a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). However, integration of fabrication of the multi-gate devices can be challenging.

### BRIEF DESCRIPTION OF THE DRAWINGS

Aspects of the present disclosure are best understood from the following detailed description when read with the accompanying Figures. It should be noted that, in accordance with the standard practice in the industry, various features are not drawn to scale. In fact, the dimensions of the various features may be arbitrarily increased or reduced for clarity of discussion.

FIGS. 1A to 1C illustrate diagrammatic perspective views of intermediate stages of manufacturing a semiconductor structure in accordance with some embodiments.

FIGS. 2A-1 to 2M-1, 2A-2 to 2M-2, 2A-3 to 2M-3, and 2A-4 to 2M-4 illustrate the cross-sectional views of intermediate stages of manufacturing the semiconductor structure shown along line Y_{SD}-Y_{SD}′, Y_{MG}-Y_{MG}′, X₁-X₁′, and X₂-X₂′ in FIG. 1C, respectively, in accordance with some embodiments.

FIG. 2F-5 illustrates enlarged cross-sectional views of the region R_{2F-5} shown in FIG. 2F-3 in accordance with various embodiments.

FIG. 2F-6 illustrates enlarged cross-sectional views of the region R_{2F-6} shown in FIG. 2F-3 in accordance with various embodiments.

FIGS. 2G-5, 2G-6, and 2G-7 illustrate enlarged cross-sectional views of the region R_{2G} shown in FIG. 2G-3 in accordance with various embodiments.

FIG. 2H-5 illustrates enlarged cross-sectional views of the region R_{2H-3} shown in FIG. 2H-3 in accordance with various embodiments.

FIG. 2H-6 illustrates enlarged cross-sectional views of the region R_{2H-4} shown in FIG. 2H-4 in accordance with various embodiments.

FIG. 2J-5 illustrates enlarged cross-sectional views of the region R_{2J-3} shown in FIG. 2J-3 in accordance with various embodiments.

FIG. 2J-6 illustrates enlarged cross-sectional views of the region R_{2J-4} shown in FIG. 2J-4 in accordance with various embodiments.

FIG. 2K-5 illustrates enlarged cross-sectional views of the region R_{2K-3} shown in FIG. 2K-3 in accordance with various embodiments.

FIG. 2K-6 illustrates enlarged cross-sectional views of the region R_{2K-4} shown in FIG. 2K-4 in accordance with various embodiments.

FIG. 2L-5 illustrates enlarged cross-sectional views of the region R_{2L-3} shown in FIG. 2L-3 in accordance with various embodiments.

FIG. 2L-6 illustrates enlarged cross-sectional views of the region R_{2L-4} shown in FIG. 2L-4 in accordance with various embodiments.

FIG. 2M-5 illustrates enlarged cross-sectional views of the region R_{2M-3} shown in FIG. 2M-3 in accordance with various embodiments.

FIG. 2M-6 illustrates enlarged cross-sectional views of the region R_{2M-4} shown in FIG. 2M-4 in accordance with various embodiments.

FIG. 2M-7 illustrates enlarged cross-sectional views of the region R_{2M-3W} shown in FIG. 2M-3 in accordance with various embodiments.

FIG. 2M-8 illustrates enlarged cross-sectional views of the region R_{2M-4W} shown in FIG. 2M-4 in accordance with various embodiments.

FIGS. 3A, 3B, 3C, and 3D illustrate cross-sectional views of a semiconductor structure in accordance with some embodiments.

FIG. 3E illustrates enlarged cross-sectional views of the region R_{3C} shown in FIG. 3C in accordance with various embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The nanostructure transistors (e.g. nanosheet transistors, nanowire transistors, multi-bridge channel transistors, nano-ribbon FET, and gate all around (GAA) transistors) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanostructures.

Embodiments of semiconductor structures and methods for forming the same are provided. The semiconductor structures may include channel structures, a gate structure wrapping around the channel structures, and source/drain structures attached to the channel structures. In addition, air gaps are formed in the semiconductor structure to electrically and physically separate the gate structure and the source/drain structures. Since the dielectric constrant (k) value of the air gaps is low, the capacitance of the resulting devices may be reduced. In addition, the air gap may also be formed under the source/drain structure, so that the current leakage from the bottom portion of the devices may also be prevented.

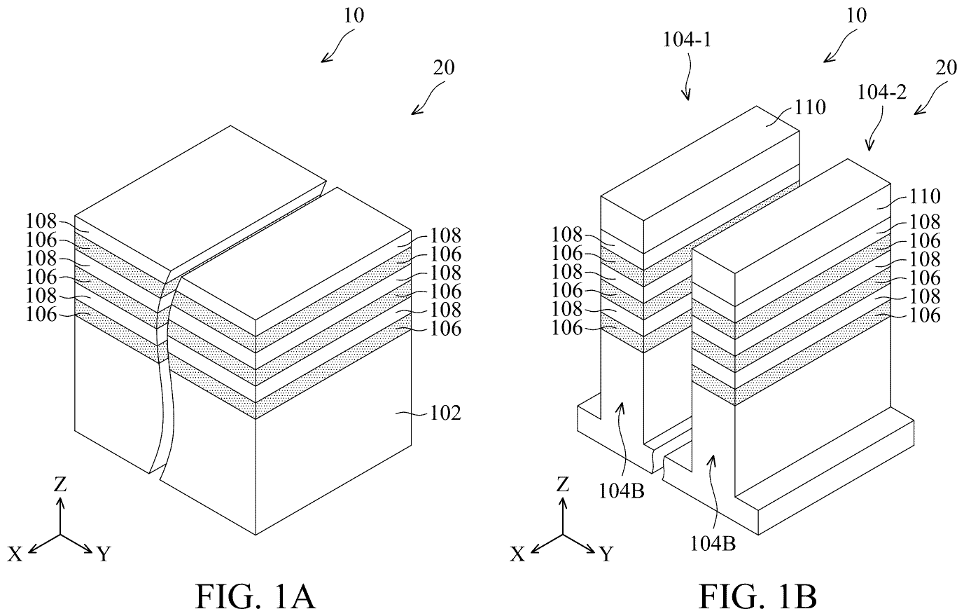

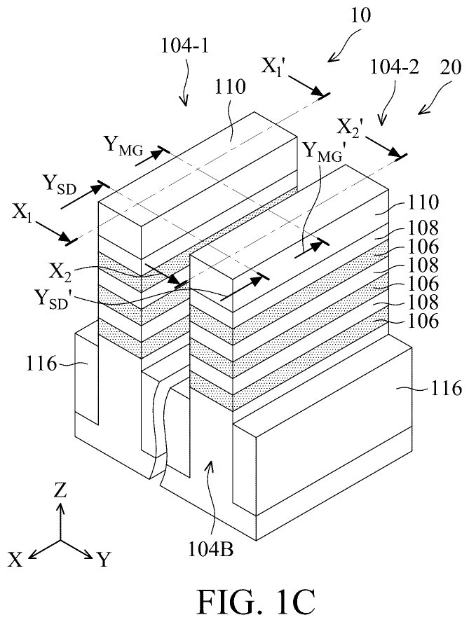

FIGS. 1A to 1C illustrate diagrammatic perspective views of intermediate stages of manufacturing a semiconductor structure 100 in accordance with some embodiments. FIGS. 2A-1 to 2M-1, 2A-2 to 2M-2, 2A-3 to 2M-3, and 2A-4 to 2M-4 illustrate the cross-sectional views of intermediate stages of manufacturing the semiconductor structure 100 shown along the lines Y_{SD}-Y_{SD}′ (i.e. in Y direction), Y_{MG}-Y_{MG}′ (i.e. in Y direction), X₁-X₁′ (i.e. in X direction), and X₂-X₂′ (i.e. in X direction) in FIG. 1C, respectively, in accordance with some embodiments. More specifically, FIGS. 2A-1, 2A-2, 2A-3, and 2A-4 illustrate the cross-sectional views of the intermediate stages of the semiconductor structure 100 shown in FIG. 1C, and FIGS. 2B-1 to 2M-1, 2B-2 to 2M-2, 2B-3 to 2M-3, and 2B-4 to 2M-4 illustrate the cross-sectional views of the intermediate stages of manufacturing the semiconductor structure 100 afterwards in accordance with some embodiments.

The semiconductor structure 100 may include multi-gate devices and may be included in a microprocessor, a memory, or other IC devices. For example, the semiconductor structure 100 may be a portion of an IC chip that includes various passive and/or active microelectronic devices such as resistors, capacitors, inductors, diodes, p-type field effect transistors (PFETs), n-type field effect transistors (NFETs), metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, other applicable components, or combinations thereof.

A substrate 102 including a first region 10 and a second region 20 is formed, and a semiconductor stack including first semiconductor material layers 106 and second semiconductor material layers 108 is formed over both the first region 10 and the second region 20 of the substrate 102, as shown in FIG. 1A in accordance with some embodiments. The first region 10 and the second region 20 may be formed next to each other, or there may be other device regions formed between them. In some embodiments, a P-type transistor is formed in the first region 10, and an N-type transistor is formed in the second region 20. For a better understanding of the semiconductor structure 100, the X-Y-Z coordinate reference is provided in the figures of the present disclosure. The X-axis and the Y-axis are generally orientated along the lateral (or horizontal) directions that are parallel to the main surface of the substrate 102. The Y-axis is transverse (e.g., substantially perpendicular) to the X-axis. The Z-axis is generally oriented along the vertical direction that is perpendicular to the main surface of the substrate 102 (or the X-Y plane).

The substrate 102 may be a semiconductor wafer such as a silicon wafer. Alternatively or additionally, the substrate 102 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

In some embodiments, the first semiconductor material layers 106 and the second semiconductor material layers 108 are alternately stacked over the substrate 102 to form the semiconductor stack. In some embodiment, the first semiconductor material layers 106 and the second semiconductor material layers 108 are made of different semiconductor materials. In some embodiments, the first semiconductor material layers 106 are made of SiGe, and the second semiconductor material layers 108 are made of silicon. In some embodiments, the Ge concentration in the first semiconductor material layers 106 is in a range from about 35 atm % to about 50 atm %.

It should be noted that although three first semiconductor material layers 106 and three second semiconductor material layers 108 are shown in FIG. 1A, the semiconductor stack may include less or more of the first semiconductor material layers 106 and the second semiconductor material layers 108 alternately stacked. For example, the semiconductor stack may include two to five of the first semiconductor material layers 106 and two to five of the second semiconductor material layers 108.

The first semiconductor material layers 106 and the second semiconductor material layers 108 may be formed by using low-pressure chemical vapor deposition (LPCVD), epitaxial growth process, another suitable method, or a combination thereof. In some embodiments, the epitaxial growth process includes molecular beam epitaxy (MBE), metal organic chemical vapor deposition (MOCVD), or vapor phase epitaxy (VPE).

After the first semiconductor material layers 106 and the second semiconductor material layers 108 are formed as the semiconductor stack over the substrate 102, the semiconductor stack is patterned to form a fin structure 104-1 in the first region 10 and a fin structure 104-2 in the second region 20, as shown in FIG. 1B in accordance with some embodiments. The fin structures 104-1 and 104-2 may extend lengthwise in X direction. In some embodiments, the patterning process includes forming a mask structure 110 over the semiconductor material stack and etching the semiconductor material stack and the underlying substrate 102 through the mask structure 110. In some embodiments, the mask structure 110 is a multilayer structure including a pad oxide layer and a nitride layer formed over the pad oxide layer. The pad oxide layer may be made of silicon oxide, which is formed by thermal oxidation or CVD, and the nitride layer may be made of silicon nitride, which is formed by CVD, such as LPCVD or plasma-enhanced CVD (PECVD). In some embodiments, the fin structures 104-1 and 104-2 include base fin structures 104B and the semiconductor stacks, including the first semiconductor material layers 106 and the second semiconductor material layers 108, formed over the base fin structures 104B.

After the fin structures 104-1 and 104-2 are formed, an isolation structure 116 is formed around the fin structures 104-1 and 104-2, as shown in FIGS. 1C, 2A-1, 2A-2, 2A-3, and 2A-4 in accordance with some embodiments. The isolation structure 116 is configured to electrically isolate active regions (e.g. the fin structures 104-1 and 104-2) of the semiconductor structure and is also referred to as shallow trench isolation (STI) feature in accordance with some embodiments.

More specifically, an insulating layer may be formed around and covering the fin structures 104-1 and 104-2, and the insulating layer may be recessed to form the isolation structure 116 with the fin structures 104-1 and 104-2 protruding from the top surface of the isolation structure 116. In some embodiments, the insulating layer is made of silicon oxide, silicon nitride, silicon oxynitride (SiON), another suitable insulating material, or a combination thereof. In addition, liner layers (not shown) may be formed before forming the insulating layer, and the liner layers may also be recessed with the insulating layer to form the isolation structure 116. In some embodiments, the liner layers include multiple dielectric material layers.

Afterwards, a dummy gate structure 130 is formed across the fin structures 104-1 and 104-2, as shown in FIGS. 2B-1, 2B-2, 2B-3, 2B-4 in accordance with some embodiments. The dummy gate structure 130 may be used to define the channel regions of the resulting semiconductor structure 100.

In some embodiments, the dummy gate structure 130 includes a dummy gate dielectric layer 132 and a dummy gate electrode layer 134. In some embodiments, the dummy gate dielectric layer 132 is made of one or more dielectric materials, such as silicon oxide, silicon nitride, silicon oxynitride (SiON), HfO₂, HfZrO, HfSiO, HfTiO, HfAlO, or a combination thereof. In some embodiments, the dummy gate dielectric layer 132 is formed using thermal oxidation, CVD, ALD, physical vapor deposition (PVD), another suitable method, or a combination thereof.

In some embodiments, the dummy gate electrode layer 134 is made of conductive material includes polycrystalline-silicon (poly-Si), poly-crystalline silicon-germanium (poly-SiGe), or a combination thereof. In some embodiments, the dummy gate electrode layer 134 is formed using CVD, PVD, or a combination thereof.

In some embodiments, a hard mask layer 137 is formed over the dummy gate electrode layer 134. In some embodiments, the hard mask layer 137 includes multiple layers, such as an oxide layer 135 and a nitride layer 136. In some embodiments, the oxide layer 135 is made of silicon oxide, and the nitride layer 136 is made of silicon nitride.

The formation of the dummy gate structures 130 may include conformally forming a dielectric material as the dummy gate dielectric layers 132. Afterwards, a conductive material may be formed over the dielectric material as the dummy gate electrode layers 134, and the hard mask layer 137 may be formed over the conductive material. Next, the dielectric material and the conductive material may be patterned through the hard mask layer 137 to form the dummy gate structures 130.

After the dummy gate structure 130 is formed, a spacer layer 138 is formed to cover the top surfaces and the sidewalls of the dummy gate structures 130 and the fin structures 104-1 and 104-2, as shown in FIGS. 2C-1, 2C-2, 2C-3, and 2C-4 in accordance with some embodiments. In some embodiments, the spacer layer 138 is made one or more dielectric materials. The dielectric materials may include silicon oxide (SiO₂), silicon nitride (SiN), silicon carbide (SiC), silicon oxynitride (SiON), silicon carbon nitride (SiCN), silicon oxide carbonitride (SiOCN), or a combination thereof.

After the spacer layer 138 is formed, an etching process is performed to form gate spacers 140 and fin spacers 142 with the spacer layer 138 and to form source/drain recesses 144 in the fin structures 104-1 and 104-2, as shown in FIGS. 2D-1, 2D-2, 2D-3, and 2D-4 in accordance with some embodiments. The gate spacers 140 may be configured to separate source/drain structures (formed afterwards) from the dummy gate structure 130, and the fin spacers 142 may be configured to confine the growth of the source/drain structures formed therein.

More specifically, the spacer layer 138 is etched to form the gate spacers 140 on opposite sidewalls of the dummy gate structure 130 and to form the fin spacers 142 covering the sidewalls of the fin structures 104-1 and 104-2 in accordance with some embodiments. In addition, the portions of the fin structures 104-1 and 104-2 not covered by the dummy gate structure 130 and the gate spacers 140 are etched to form the source/drain recesses 144 during the etching process in accordance with some embodiments. The etching process may be an anisotropic etching process, such as dry plasma etching, and the dummy gate structure 130 and the gate spacers 140 may be used as etching masks during the etching process. In some embodiments, the isolation structure 116 is also slightly etched during the etching process.

After the source/drain recesses 144 are formed, the first semiconductor material layers 106 exposed by the source/drain recesses 144 are laterally recessed to form notches 146, and the resulting structure is shown in FIGS. 2E-1, 2E-2, 2E-3, and 2E-4 in accordance with some embodiments. In some embodiments, an etching process is performed to laterally recess the first semiconductor material layers 106 of the fin structure 104-1 and 104-2 from the source/drain recesses 144. In some embodiments, during the etching process, the first semiconductor material layers 106 have a greater etching rate (or etching amount) than the second semiconductor material layers 108, thereby forming notches 146 between the adjacent second semiconductor material layers 108.

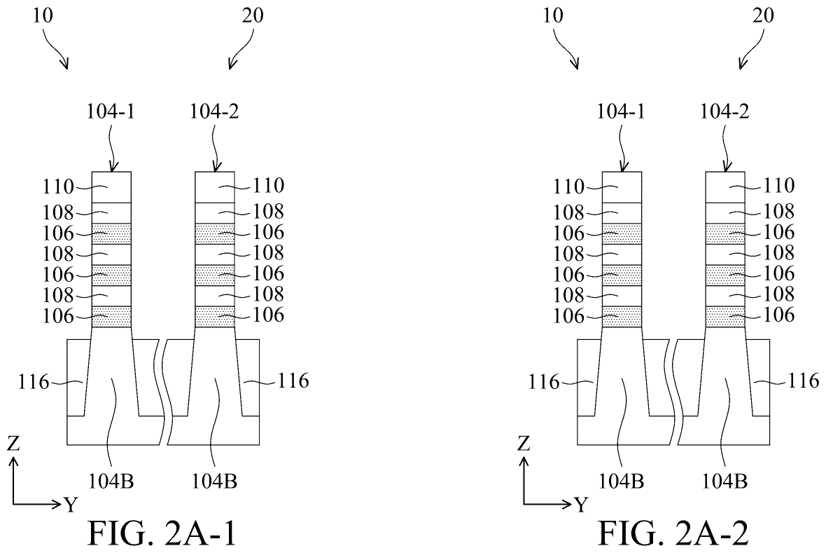

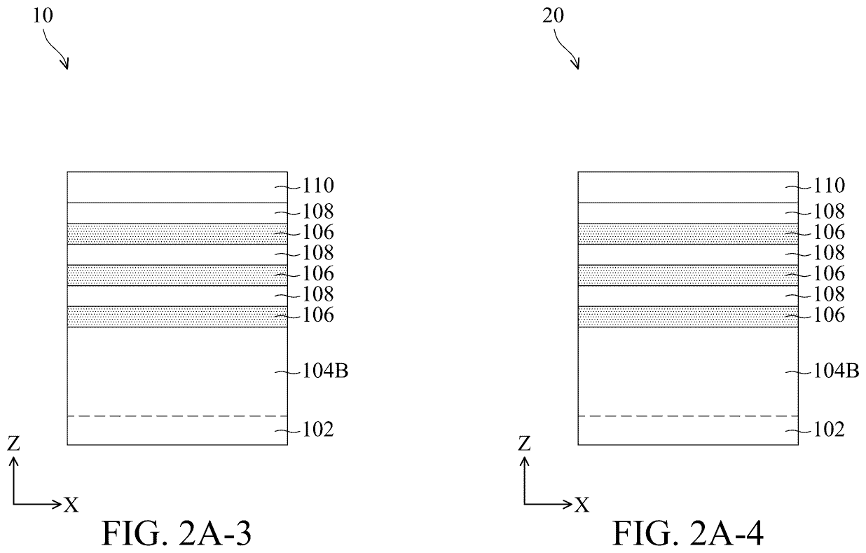

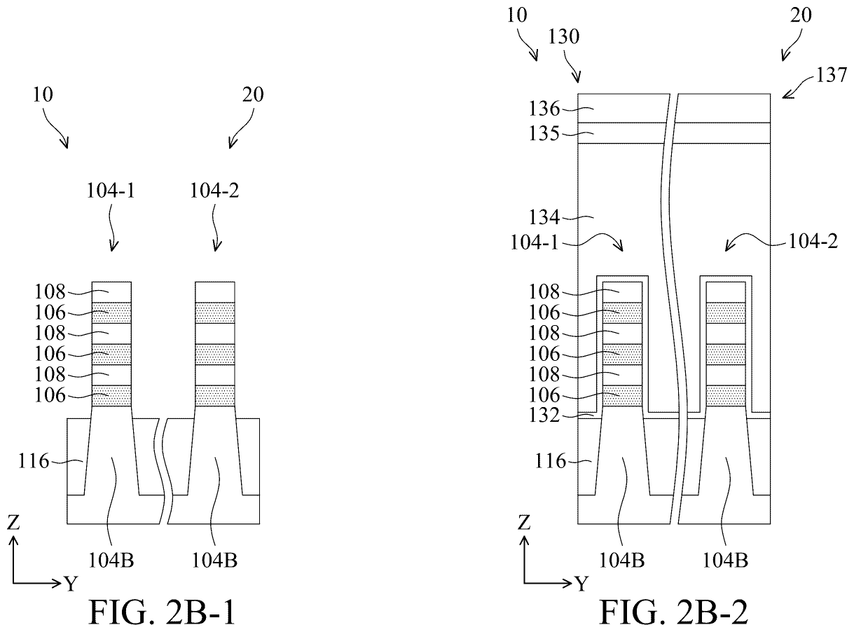

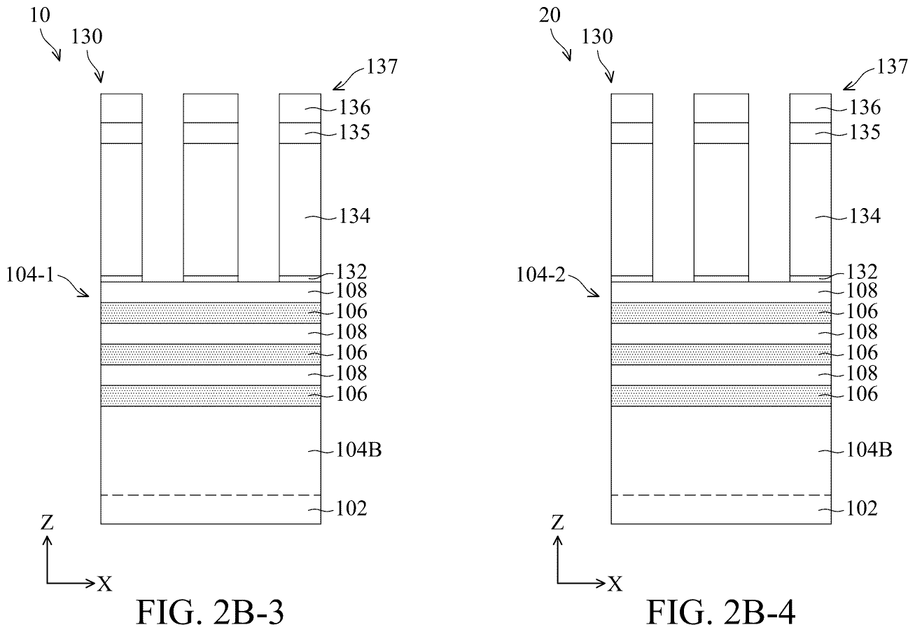

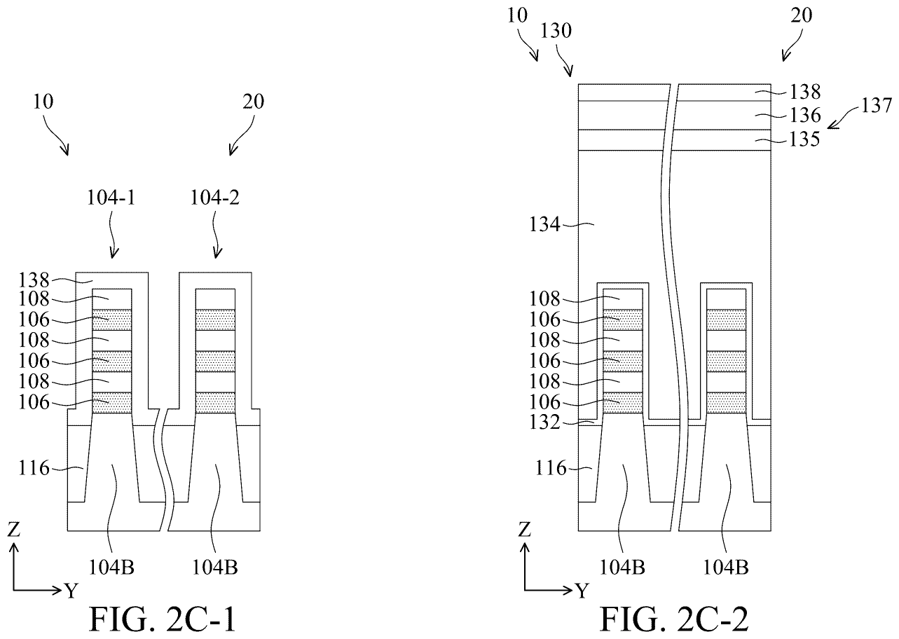

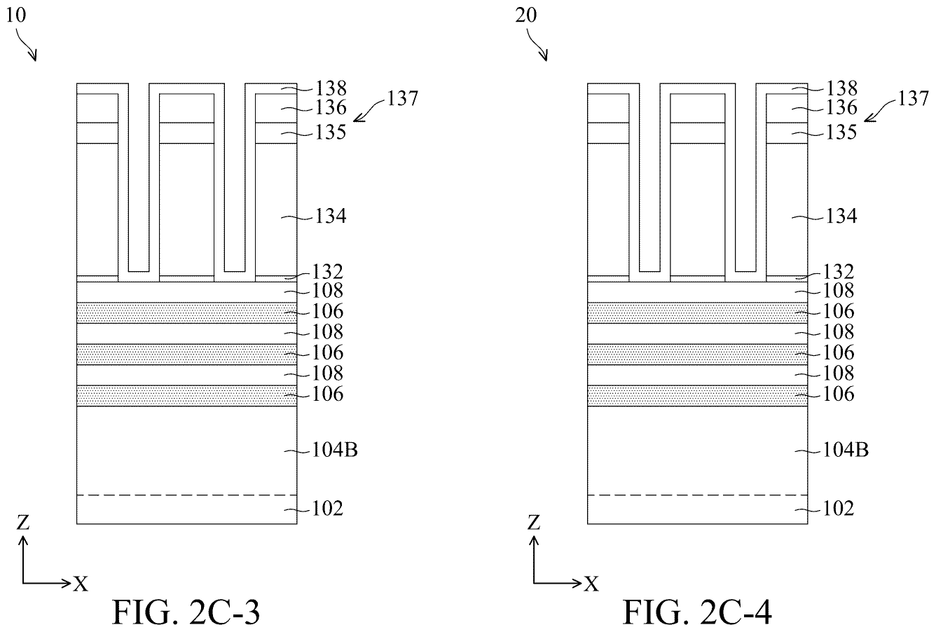

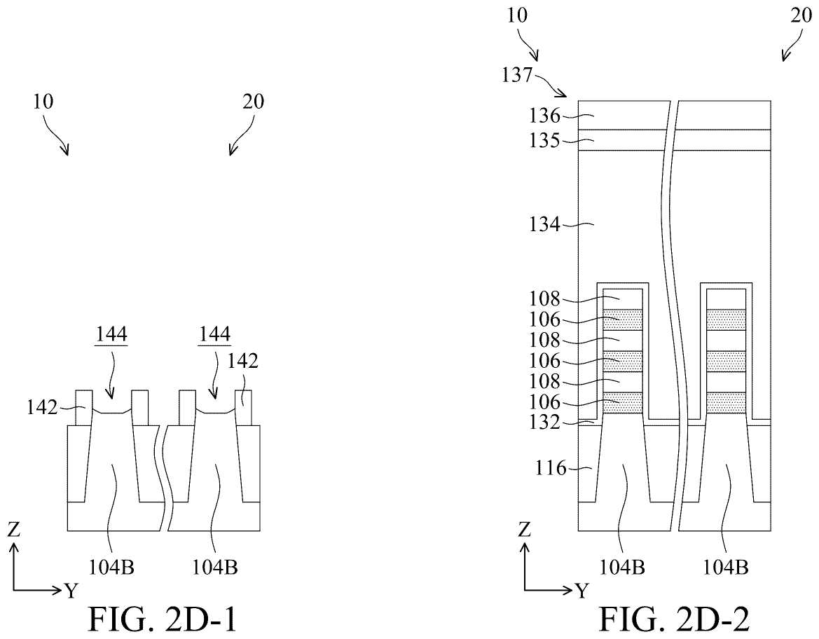

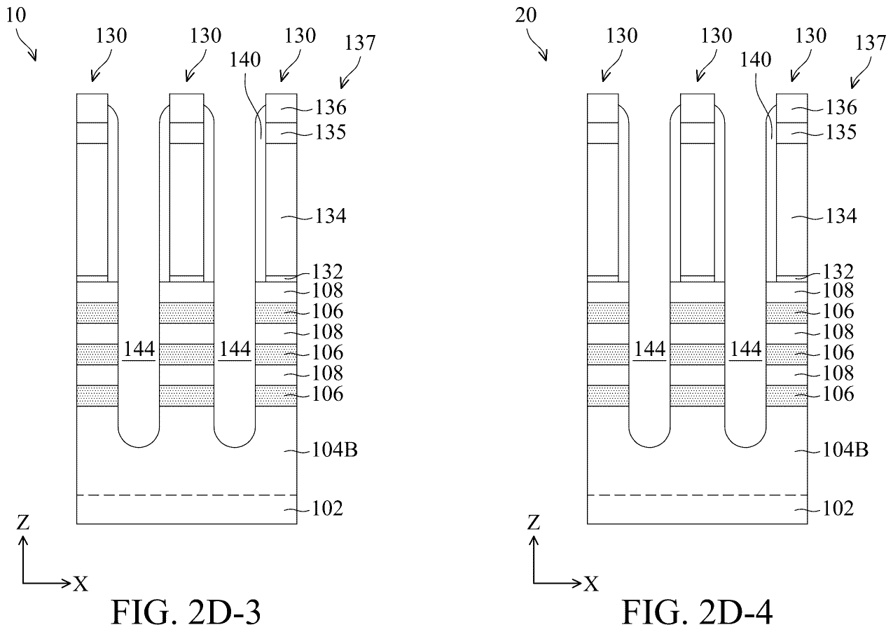

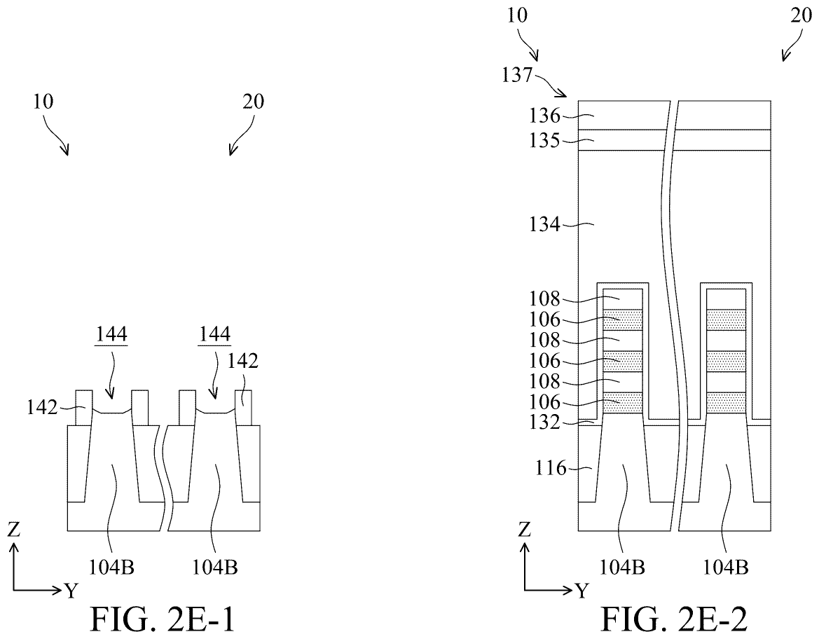

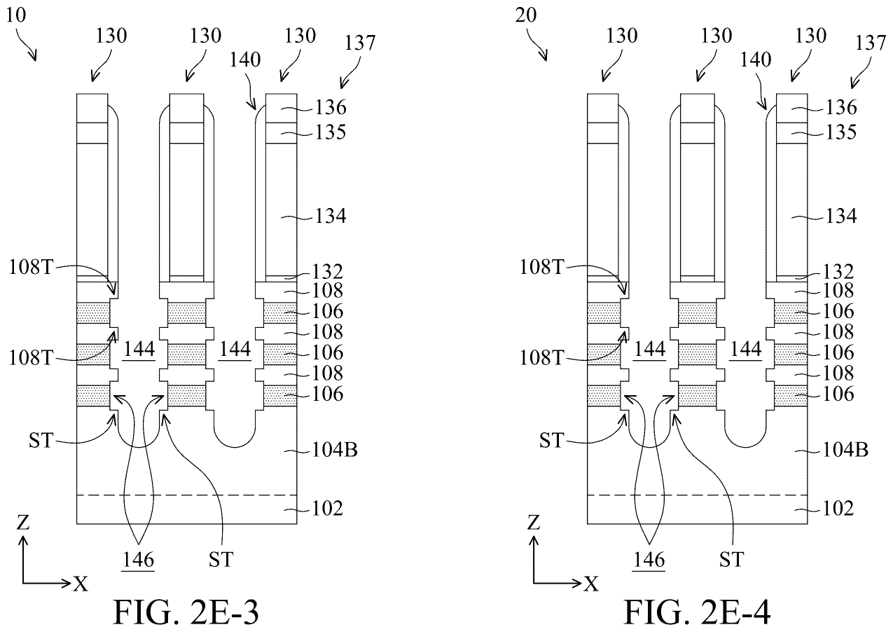

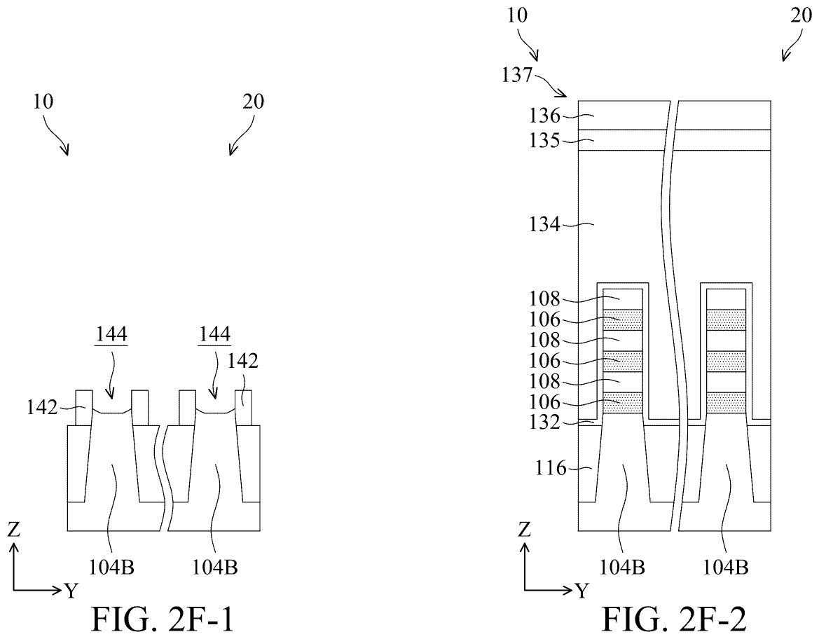

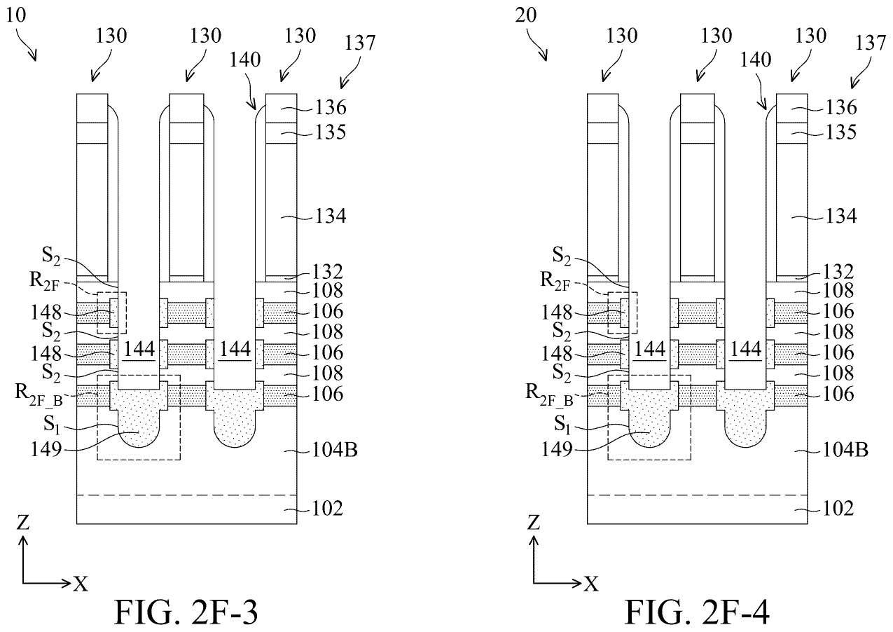

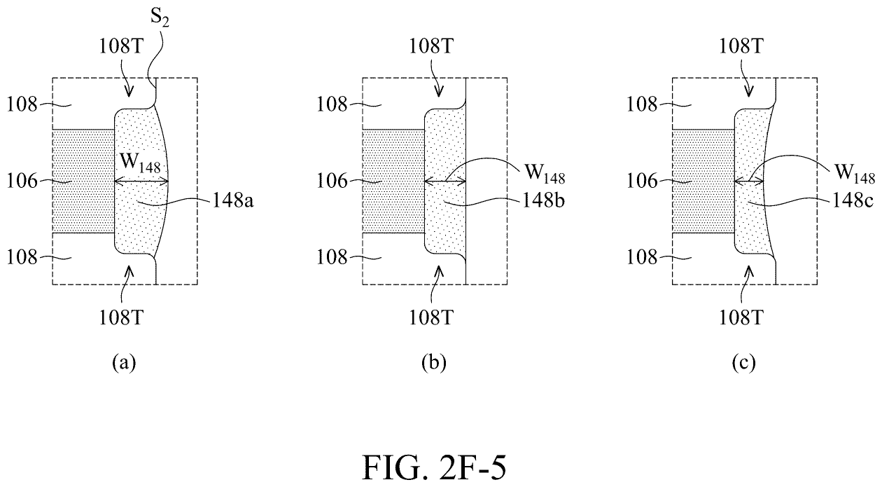

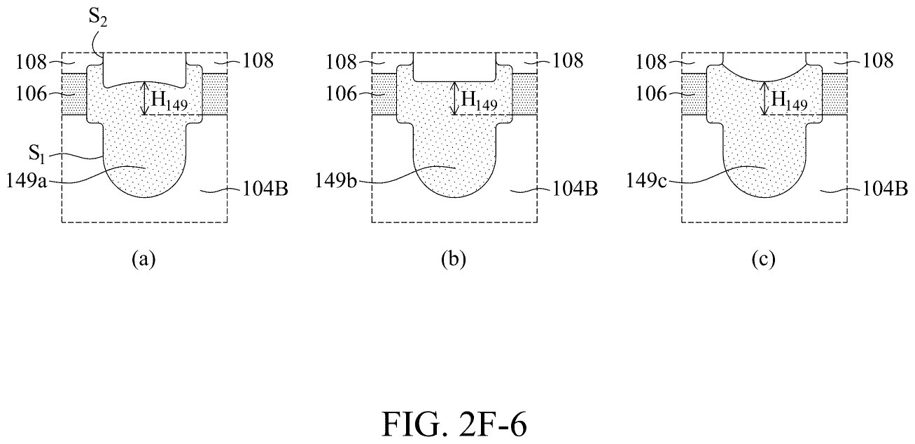

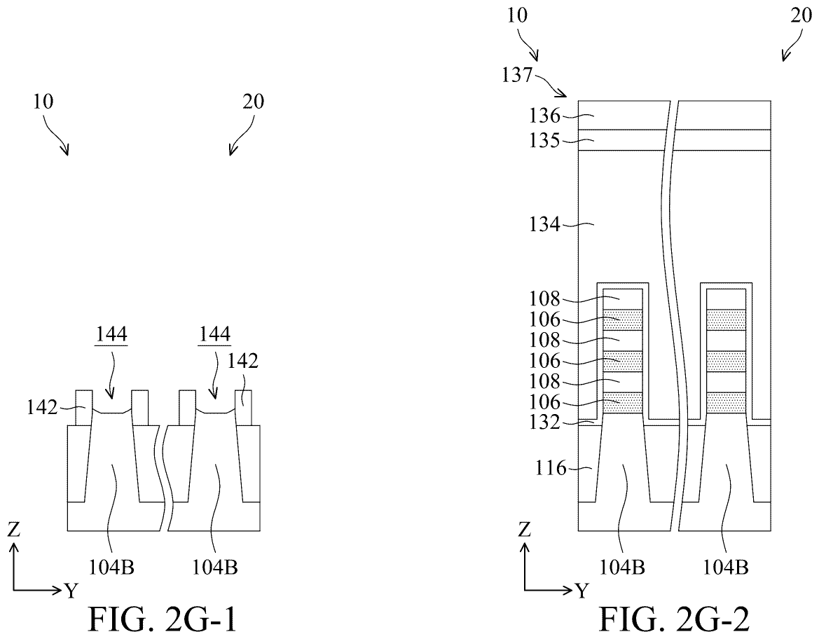

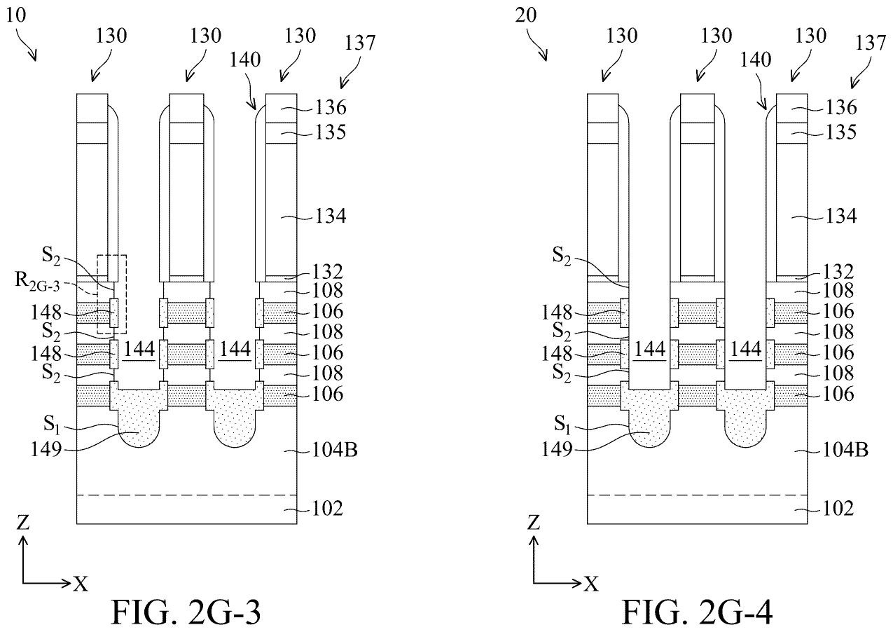

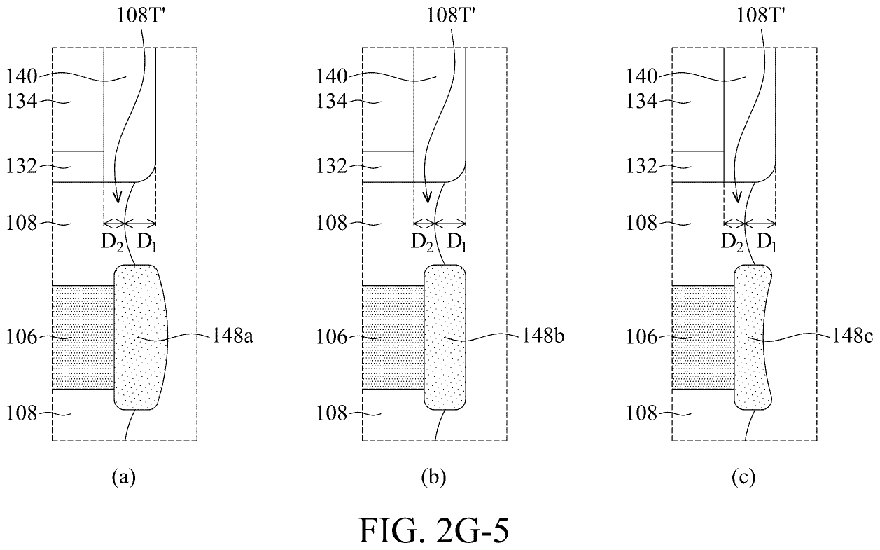

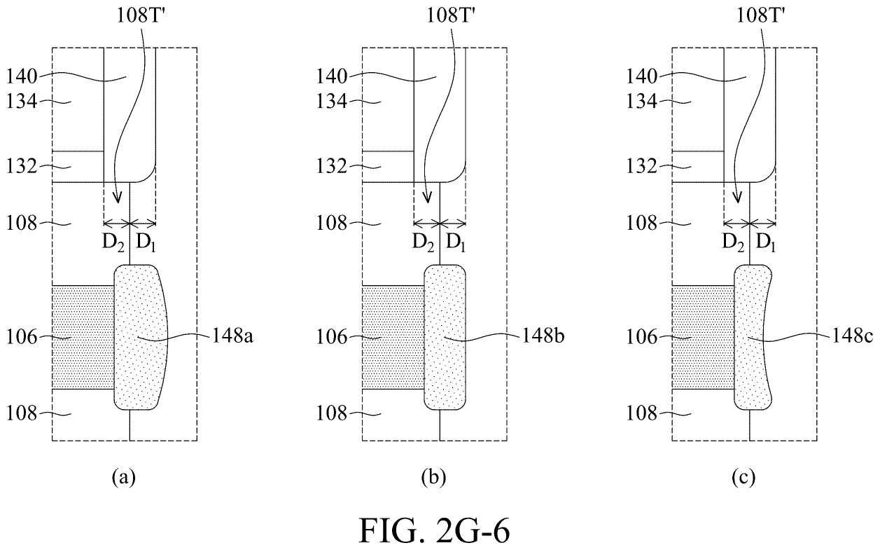

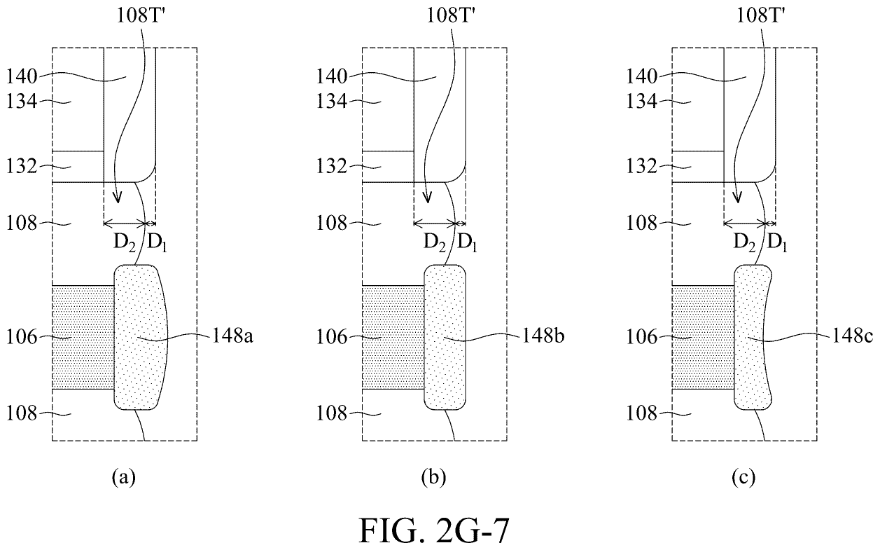

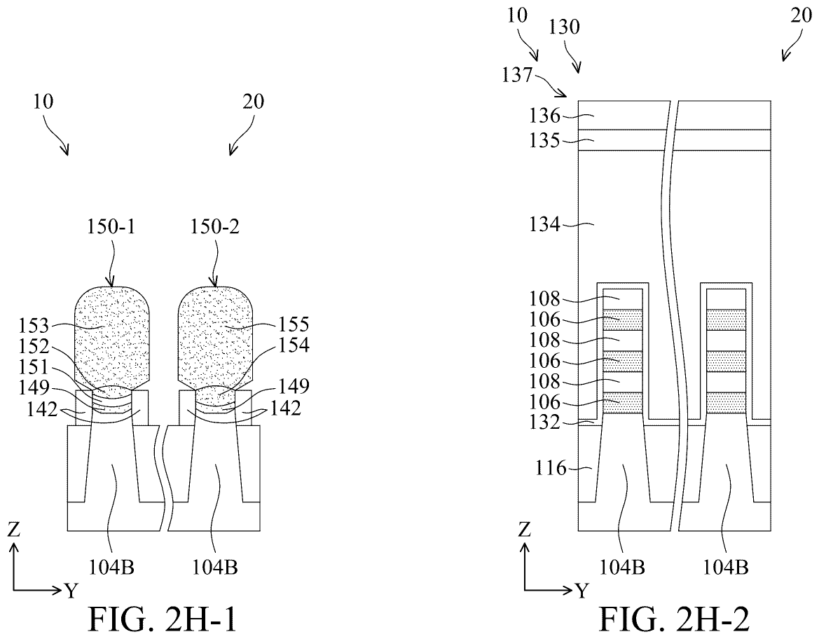

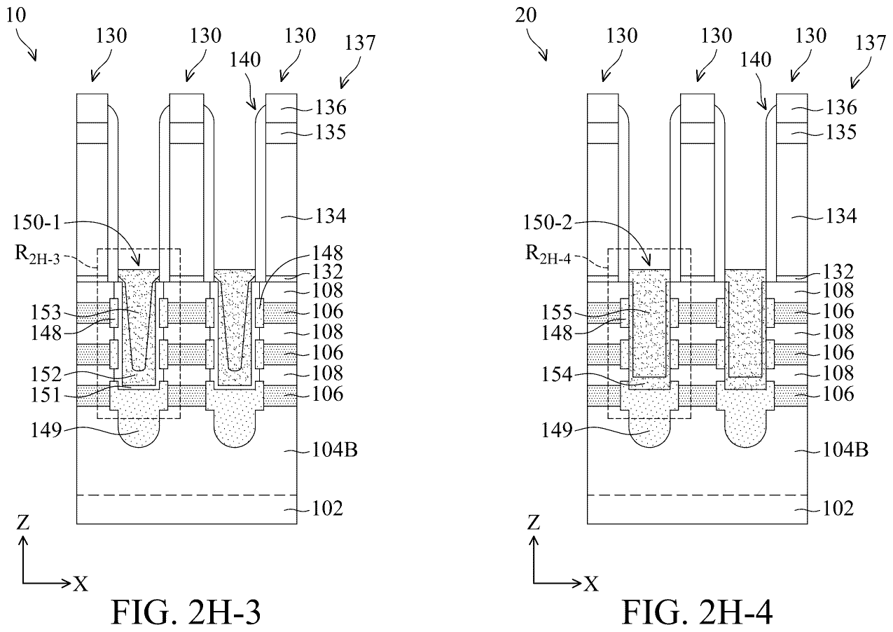

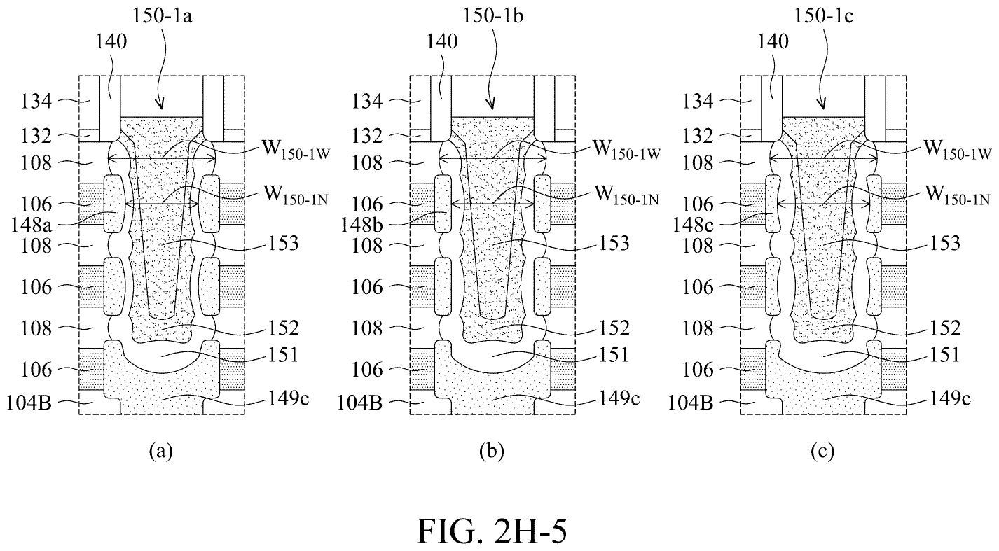

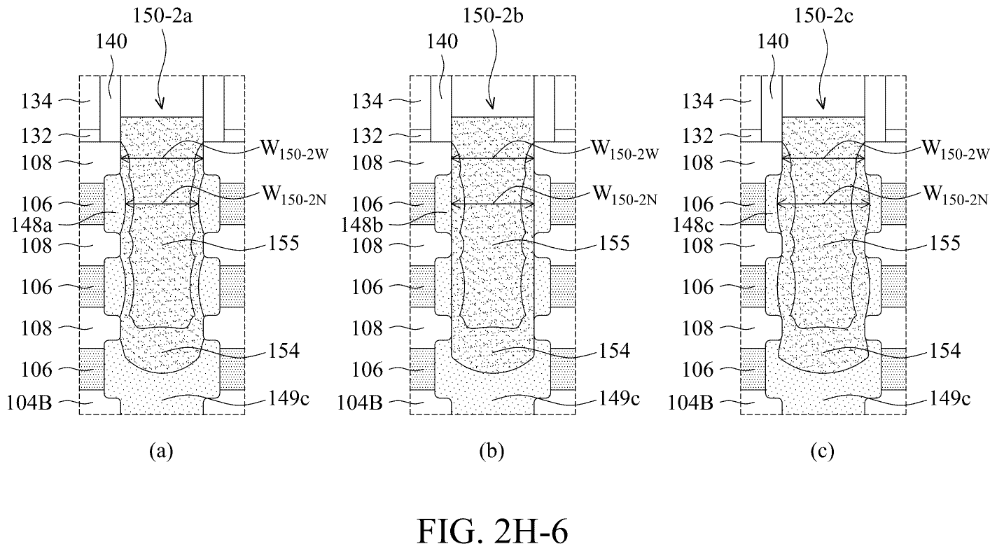

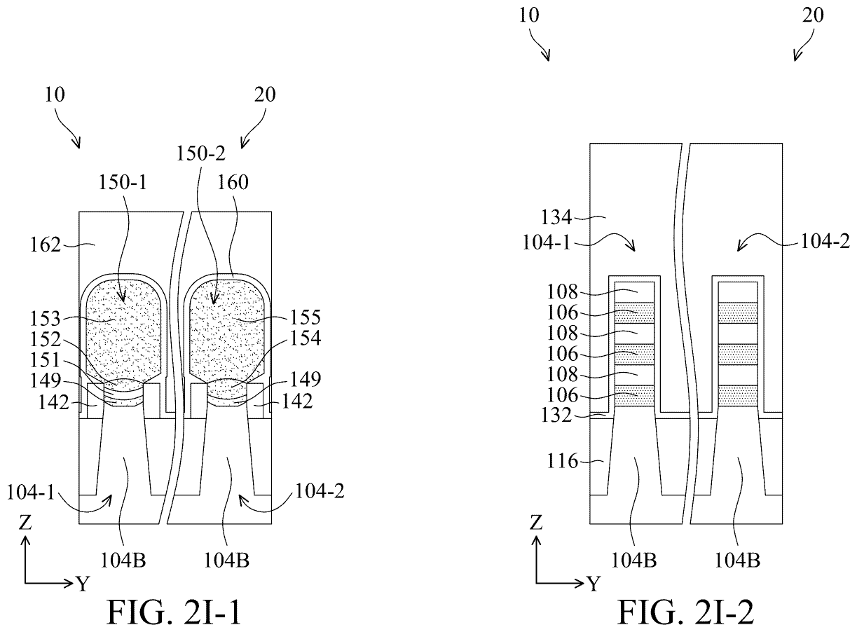

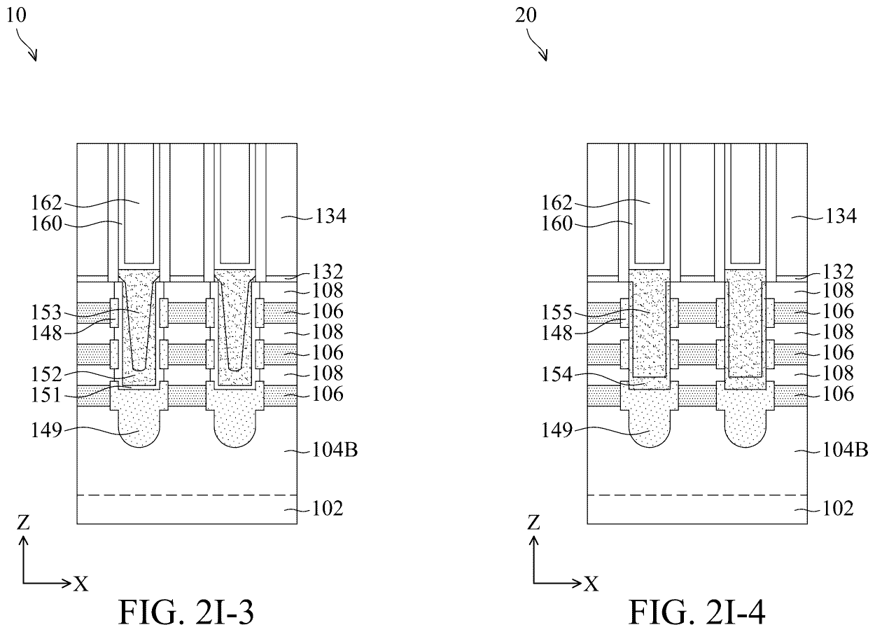

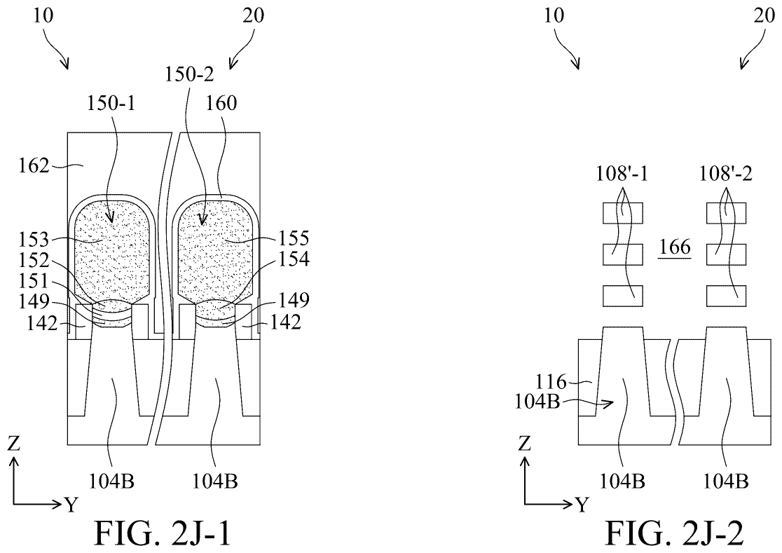

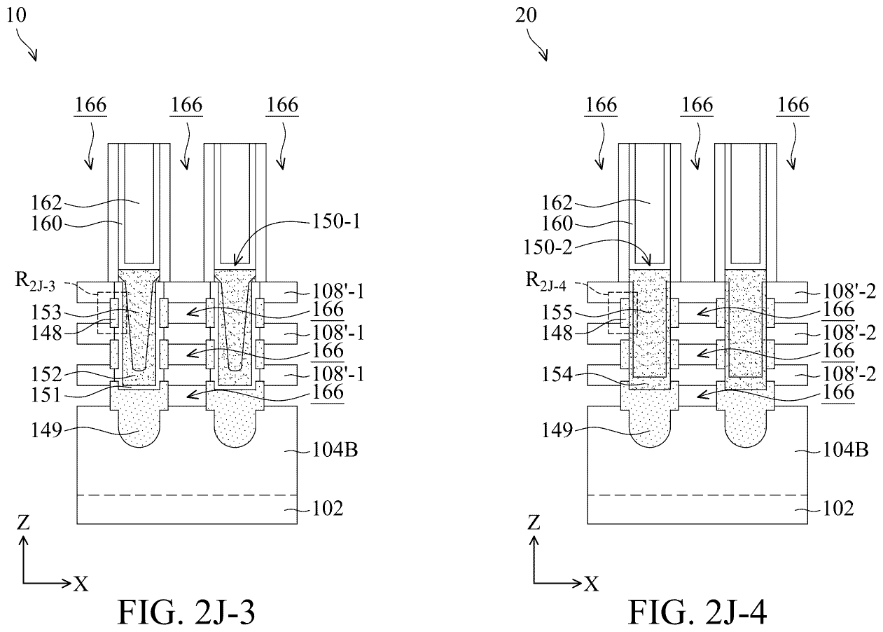

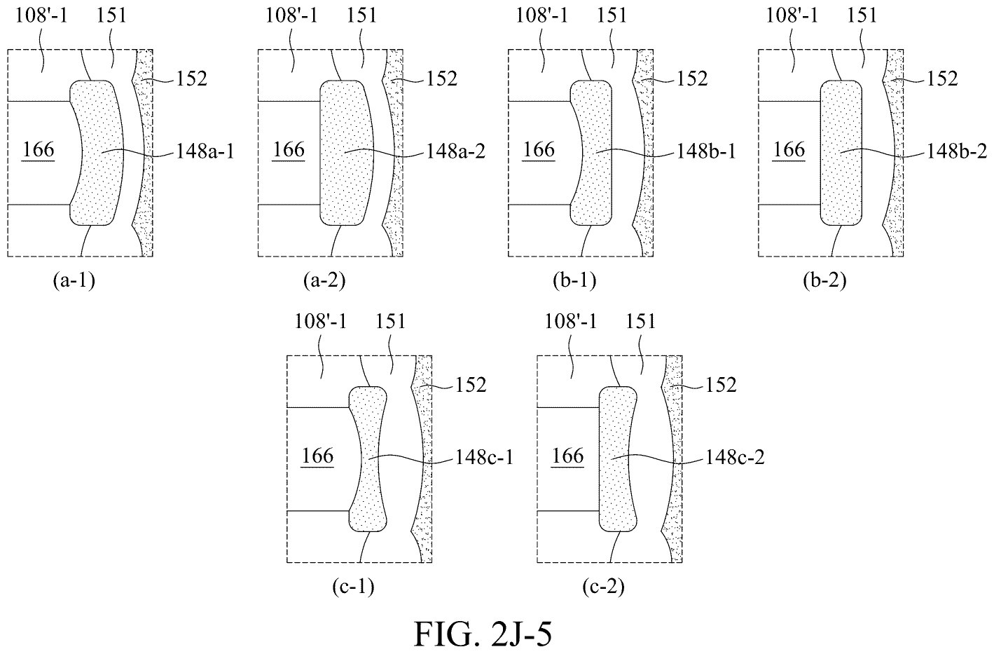

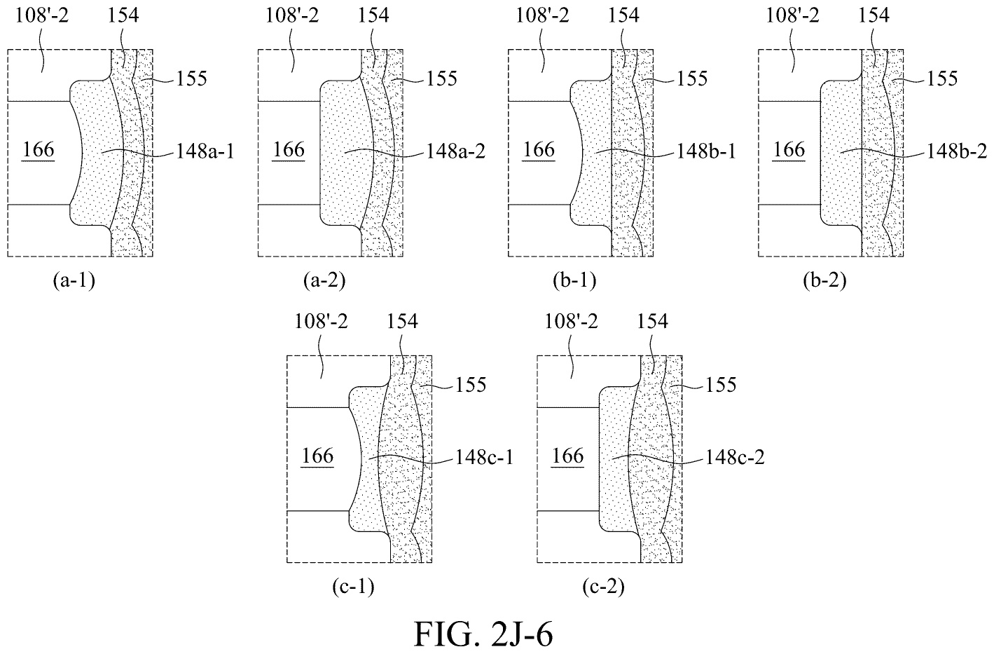

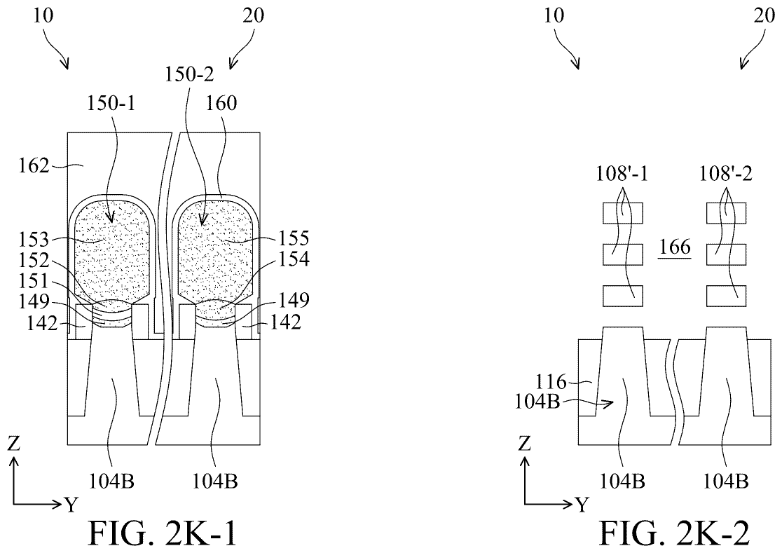

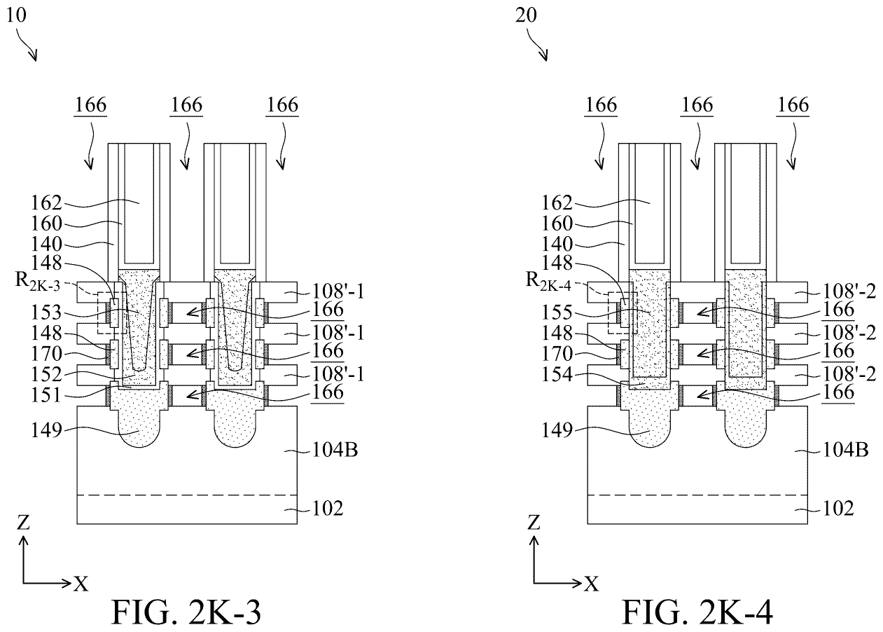

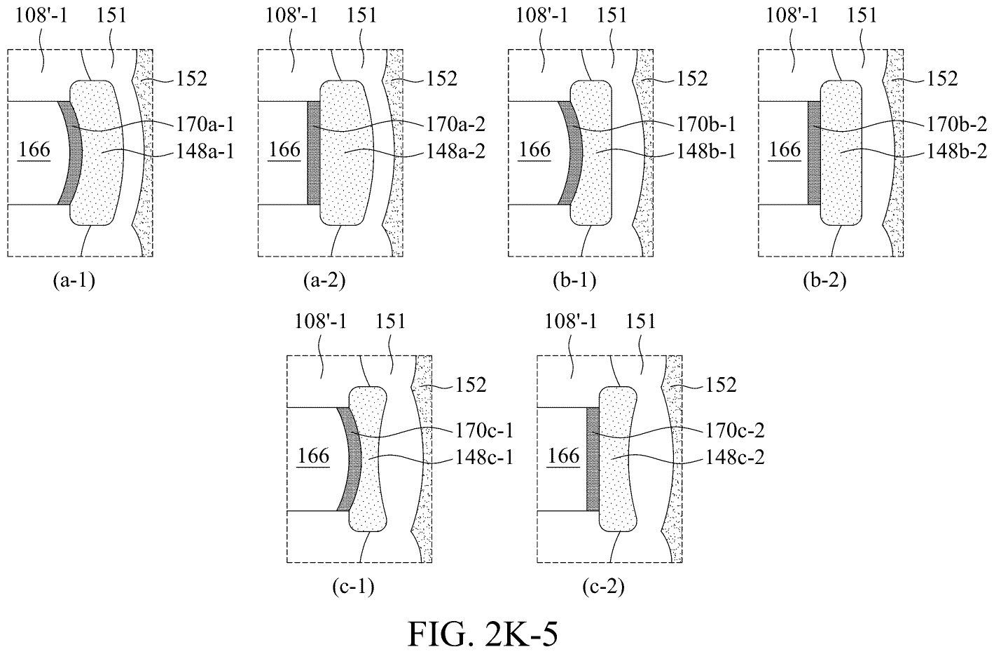

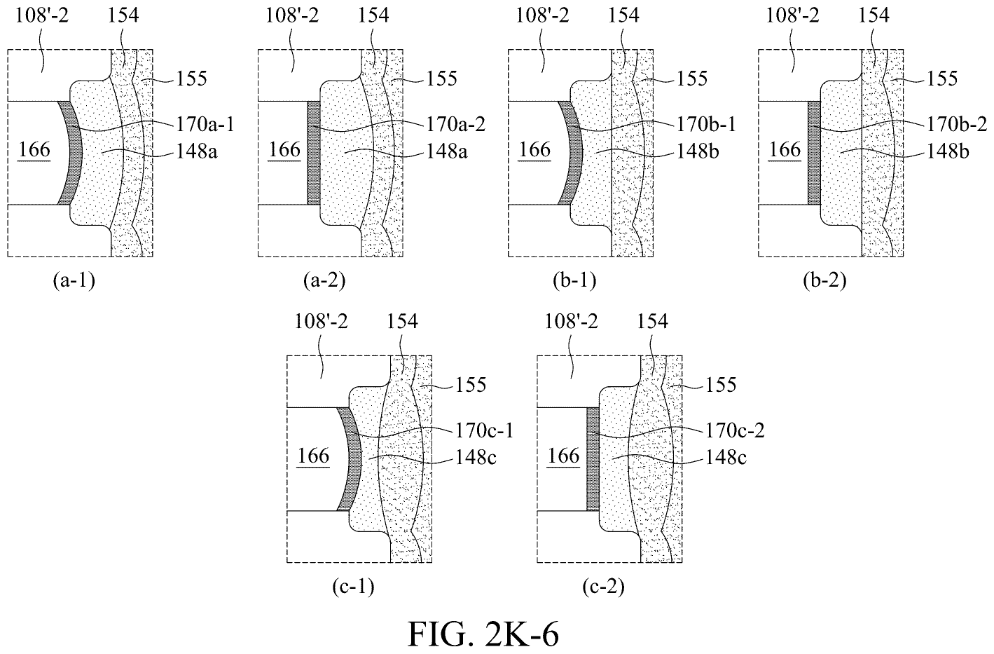

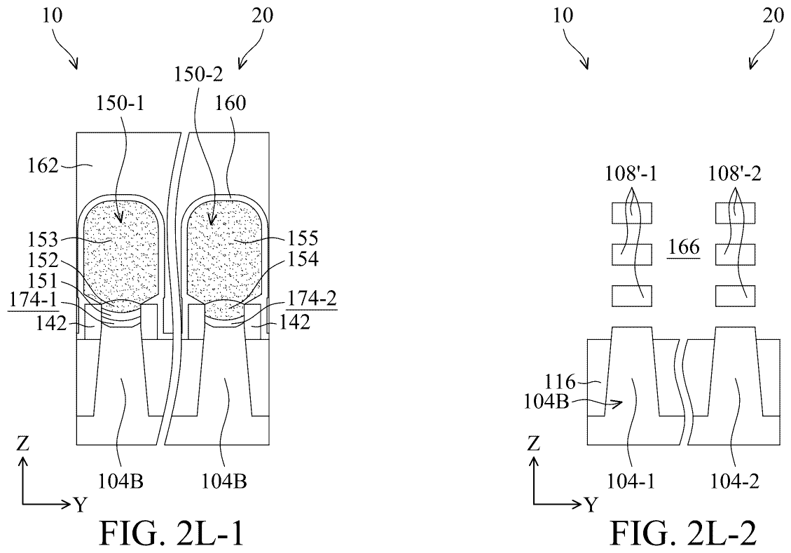

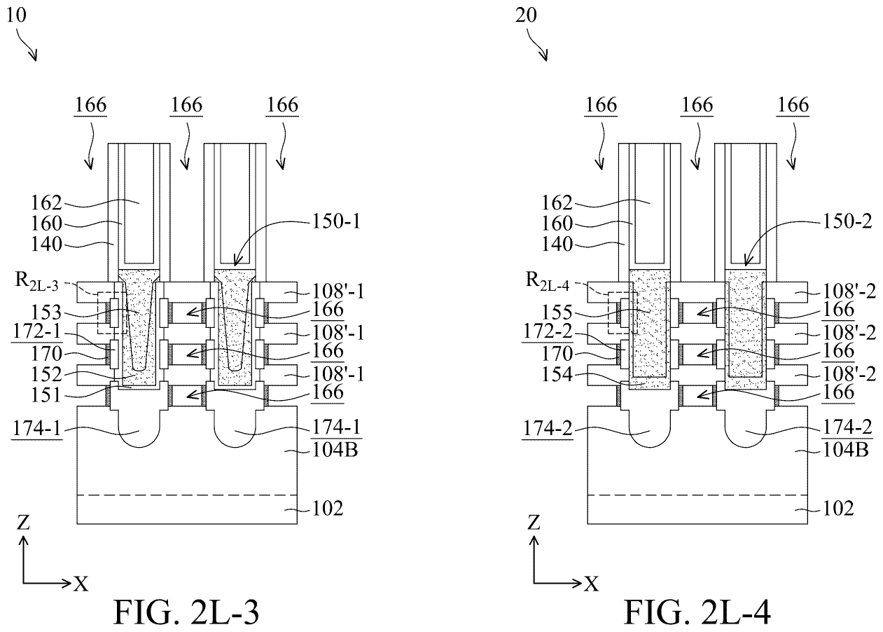

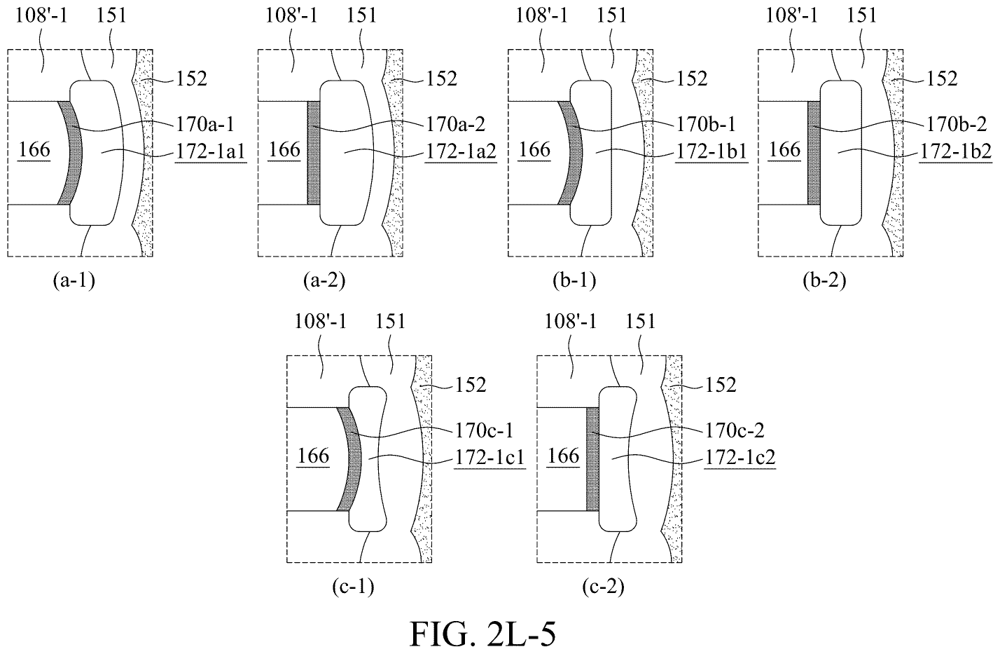

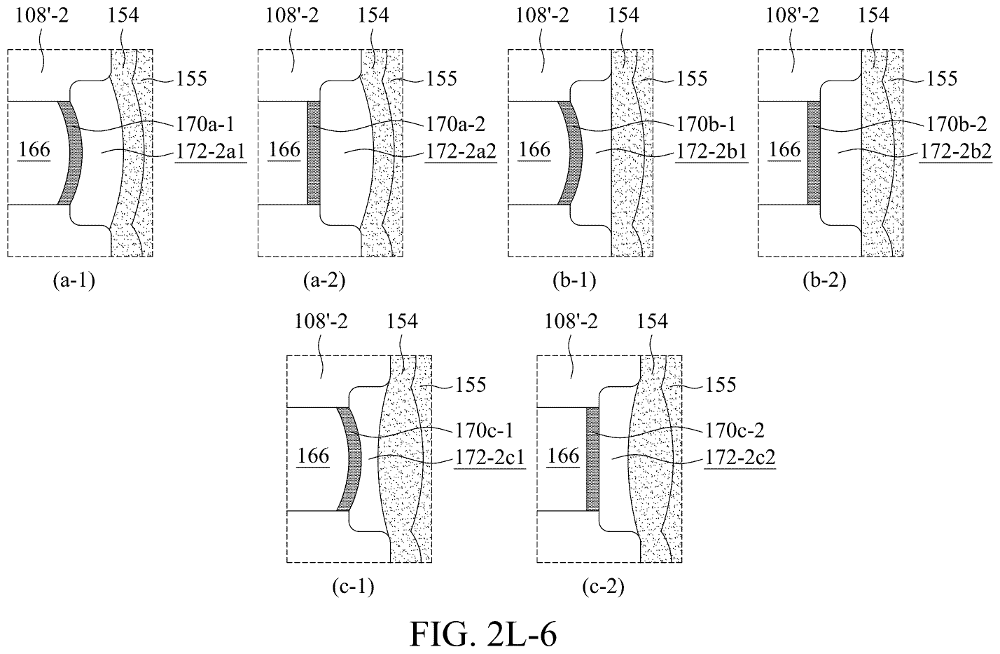

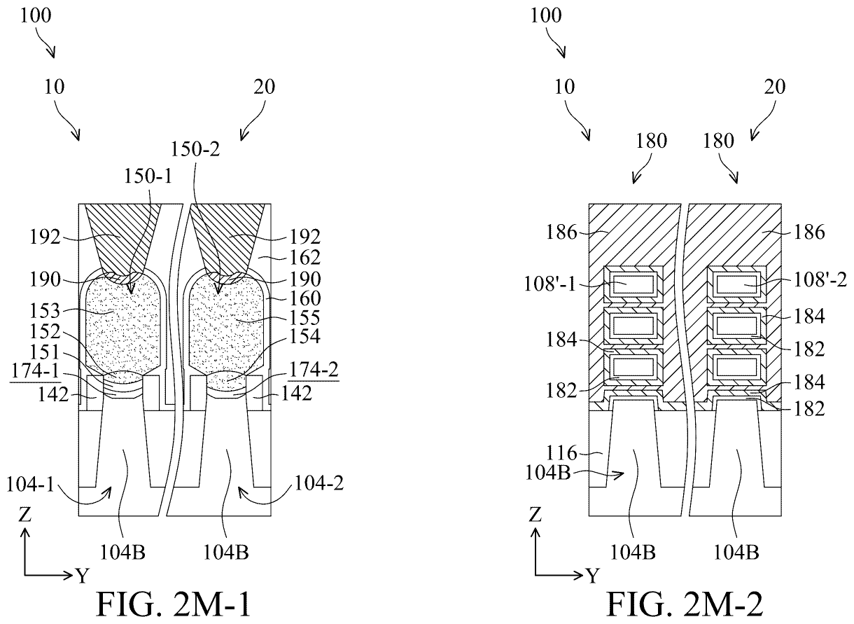

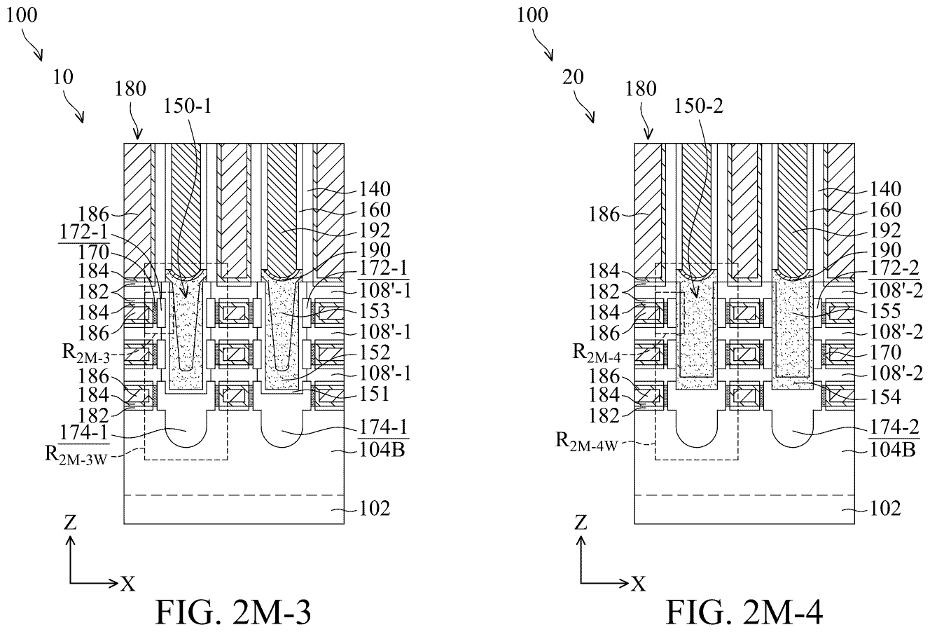

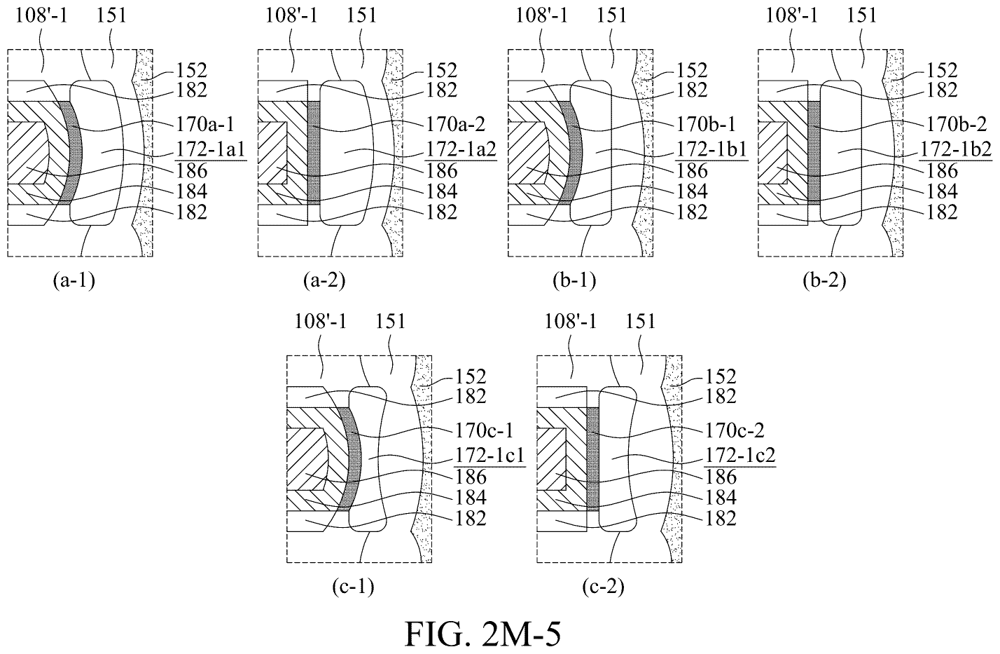

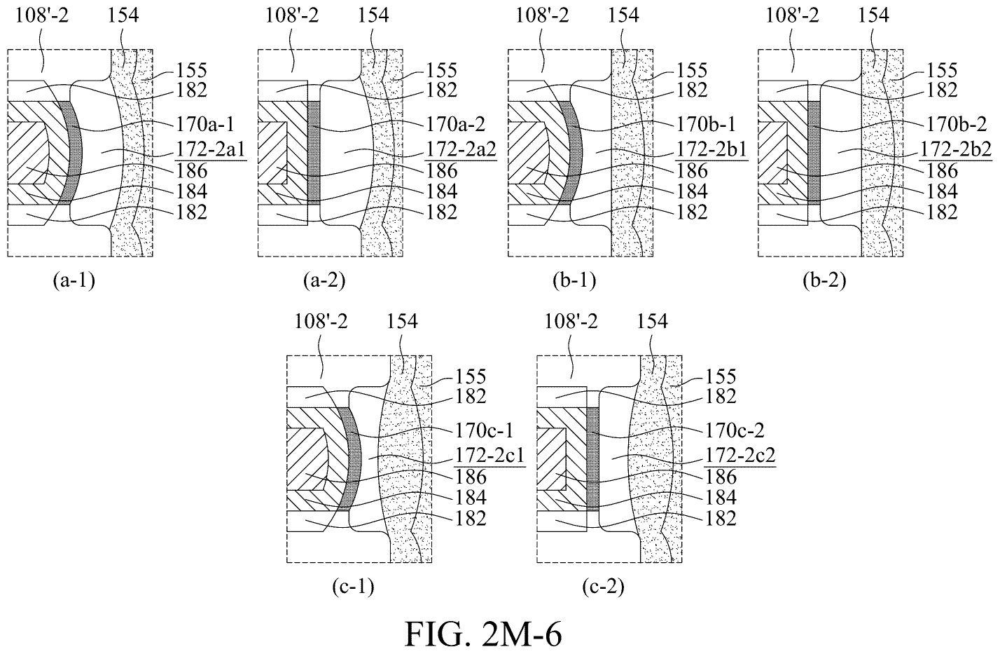

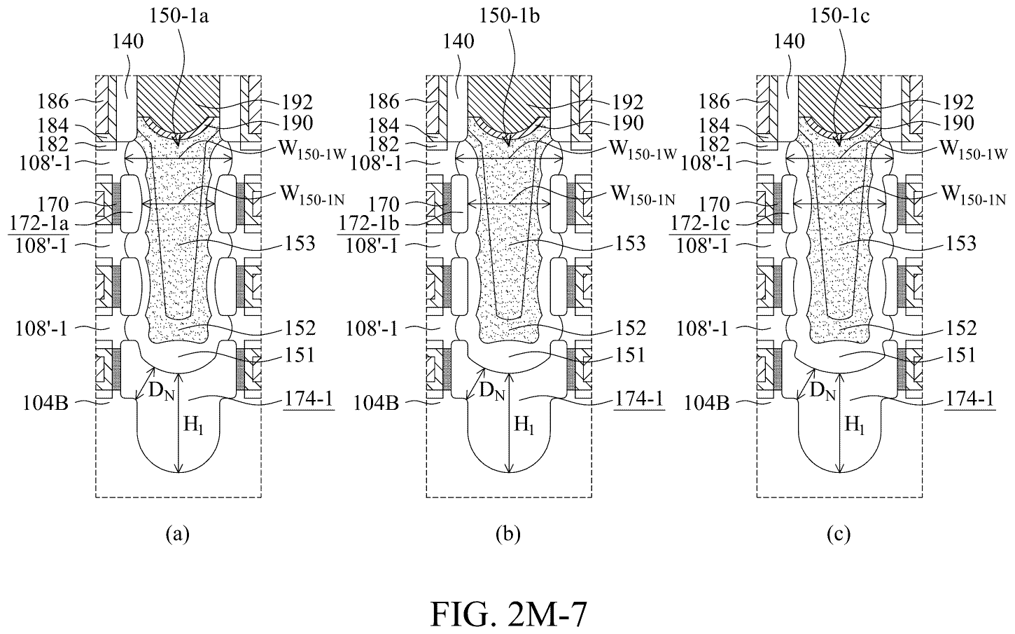

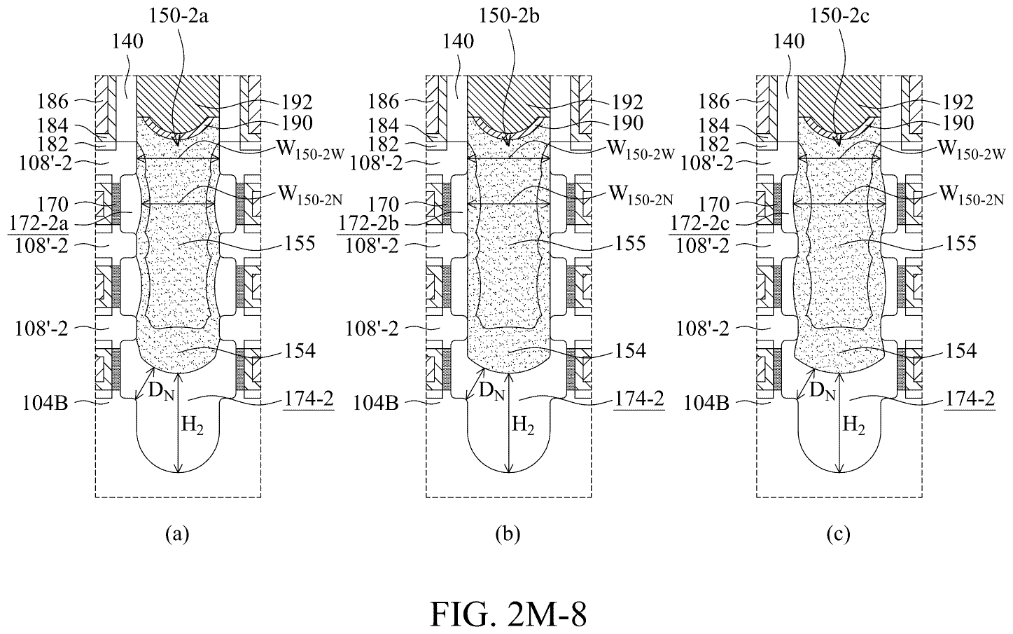

In some embodiments, the second semiconductor material layers 108 are also slightly etched during the etching process, so that the second semiconductor material layers 108 have thinned portions 108T exposed by the notches 146 in accordance with some embodiments. In some embodiments, the etching process is an isotropic etching such as dry chemical etching, remote plasma etching, wet chemical etching, another suitable technique, or a combination thereof. In some embodiments, the thinned portion 108T of the topmost one of the second semiconductor material layers 108 is thicker than (i.e. in Z direction) other thinned portions 108T of the second semiconductor material layers 108. In some embodiments, the portion of the base fin structure 104B exposed by the source/drain recess 144 has step shapes ST, as shown in FIGS. 2E-3 and 2E-4.

Next, sacrificial inner spacers 148 are formed in the notches 146 between the second semiconductor material layers 108, and a bottom sacrificial layer 149 is formed in the bottommost one of the notches 146 and extends into the bottom portion of the source/drain recess 144, and the resulting structure is shown in FIGS. 2F-1, 2F-2, 2F-3, and 2F-4 in accordance with some embodiments. The sacrificial inner spacers 148 are configured to create spaces for separating the source/drain structures and the gate structures formed in subsequent manufacturing processes. In addition, the bottom sacrificial layers 149 are configured to create spaces for separating the source/drain structures and the base fin structures 104B.

As described previously, since the second semiconductor material layers 108 are also partially etched when forming the notches 146, the sacrificial inner spacers 148 formed in the notches 146 are thicker than the thicknesses of the first semiconductor material layers 106 in accordance with some embodiments. The shapes of the sacrificial inner spacers 148 and the bottom sacrificial layer 149 may be adjusted according to their application.

FIG. 2F-5 illustrates enlarged cross-sectional views of the region R_{2F} shown in FIGS. 2F-3 and 2F-4 in accordance with various possible embodiments. That is, the sacrificial inner spacers 148 in the first region 10 and the second region 20 may have substantially the same shape at this stage. More specifically, FIG. 2F-5(a) illustrates a sacrificial inner spacer 148a having a convex surface extending between the second semiconductor material layers 108 in accordance with some embodiments. FIG. 2F-5(b) illustrates a sacrificial inner spacer 148b having a substantially vertical surface extending between the second semiconductor material layers 108 in accordance with some embodiments. FIG. 2F-5(c) illustrates a sacrificial inner spacer 148c having a concave surface extending between the second semiconductor material layers 108 in accordance with some embodiments.

In some embodiments, the width W₁₄₈ of the sacrificial inner spacer 148 (e.g. the sacrificial inner spacers 148a, 148b, and 148c) is in a range of about 3 nm to about 8 nm. As described previously, the sacrificial inner spacers 148 are configured to create spaces for separating the source/drain structures and the gate structures formed afterwards. Therefore, the sacrificial inner spacers 148 should be wide enough to separate the elements but should not to be too wide or the space for forming the gate structure may be reduced.

In addition, the second semiconductor material layers 108 have the thinned portions 108T at the edge regions, and the thinned portions 108T vertically overlap the sacrificial inner spacers 148, as shown in FIG. 2F-5 in accordance with some embodiments. In addition, the thinned portions 108T have rounded corners in accordance with some embodiments.

FIG. 2F-6 illustrates enlarged cross-sectional views of the region R_{2F-B} shown in FIGS. 2F-3 and 2F-4 in accordance with various embodiments. More specifically, FIG. 2F-6(a) illustrates a bottom sacrificial layer 149a having a convex top surface in accordance with some embodiments. FIG. 2F-6(b) illustrates a bottom sacrificial layer 149b having a substantially flat surface in accordance with some embodiments. FIG. 2F-6(c) illustrates a bottom sacrificial layer 149c having a concave top surface in accordance with some embodiments.

In some embodiments, the topmost point of the top surface of the bottom sacrificial layer 149 in the source/drain region (i.e. exposed by the source/drain recess 144) is lower than the bottom surface of the bottommost one of the second semiconductor material layers 108, so that the connection between the second semiconductor material layers 108 and the source/drain structures formed afterward will not be undermined due to the formation of the bottom sacrificial layer.

In some embodiments, the topmost point of the top surface of the bottom sacrificial layer 149 in the source/drain region (i.e. exposed by the source/drain recess 144) is higher than the top surface of the base fin structure 104B, so that the bottom portion of the source/drain structure formed afterward will be separated from the base fin structure 104B and therefore the current leakage from the bottom portion of the devices may be prevented. In some embodiments, the height difference H₁₄₉ between the topmost point of the top surface of the bottom sacrificial layer 149 in the source/drain region and the top surface of the base fin structure 104B (i.e. the bottom surface of the bottommost one of the first semiconductor material layers 106) is in a range from about 3 nm to about 5 nm in Z direction.

The sacrificial inner spacers 148 (e.g. the sacrificial inner spacers 148a, 148b, and 148c) and the bottom sacrificial layer 149 (e.g. the bottom sacrificial layer 149a, 149b, and 149c) may be made of the same material. In some embodiments, the sacrificial inner spacers 148 and the bottom sacrificial layer 149 are both made of a semiconductor material, such as SiGe. In some embodiments, the Ge in the semiconductor material for forming the sacrificial inner spacers 148 and the bottom sacrificial layer 149 is in a range of about 15 atm % to about 25 atm %. In some embodiments, the first semiconductor material layers 106, the sacrificial inner spacers 148 and the bottom sacrificial layer 149 are all made of SiGe, but the Ge concentration in the first semiconductor material layers 106 is greater than the Ge concentration in the sacrificial inner spacers 148 and the bottom sacrificial layer 149, so they may have etching selectivity during subsequent etching process.

In some embodiments, the sacrificial inner spacers 148 and the bottom sacrificial layer 149 are formed using an epitaxial growth process, such as MBE, MOCVD, VPE, other applicable epitaxial growth process, or a combination thereof. More specifically, the SiGe material may be grown from the sidewalls of the first semiconductor material layers 106 and the top surface of the base fin structure 104B exposed by the source/drain recesses 144.

In addition, although the second semiconductor material layers 108 and the base fin structure 104B may both be made of Si, they may have different surface structures exposed by the source/drain recesses 144. In some embodiments, the surface S₁ of the base fin structure 104B exposed by the source/drain recesses 144 (i.e. the bottom portion of the source/drain recesses 144) has Si (100) surface, and the sidewalls S₂ of the second semiconductor material layers 108 have Si (110) surface. Therefore, the SiG material may be grown mainly on the sidewalls of the first semiconductor material layers 106 and in the bottom portion of the source/drain recess 144 over surface S1 of the base fin structure 104B but not on the sidewalls S2 of the second semiconductor material layers 108.

After the sacrificial inner spacers 148 and the bottom sacrificial layer 149 are formed, a recessing process is performed to the first region 10, as shown in FIGS. 2G-1, 2G-2, 2G-3, and 2G-4 in accordance with some embodiments. More specifically, the thinned portions 108T of the second semiconductor material layers 108 in the first region 10 are laterally recessed (i.e. recessed in X direction), so that the dopants in the source/drain structures formed afterwards may be diffused into the second semiconductor material layers 108 in the first region 10, and the performance of the resulting device (e.g. PFET) may be improved. In some embodiments, the sacrificial inner spacers 148 and the gate spacers 140 become protruding from the sidewalls of the second semiconductor material layers 108 in accordance with some embodiments. During the recessing process, the structure in the second region 20 may be protected by a mask structure, and the mask structure may be removed after the recessing process is performed.

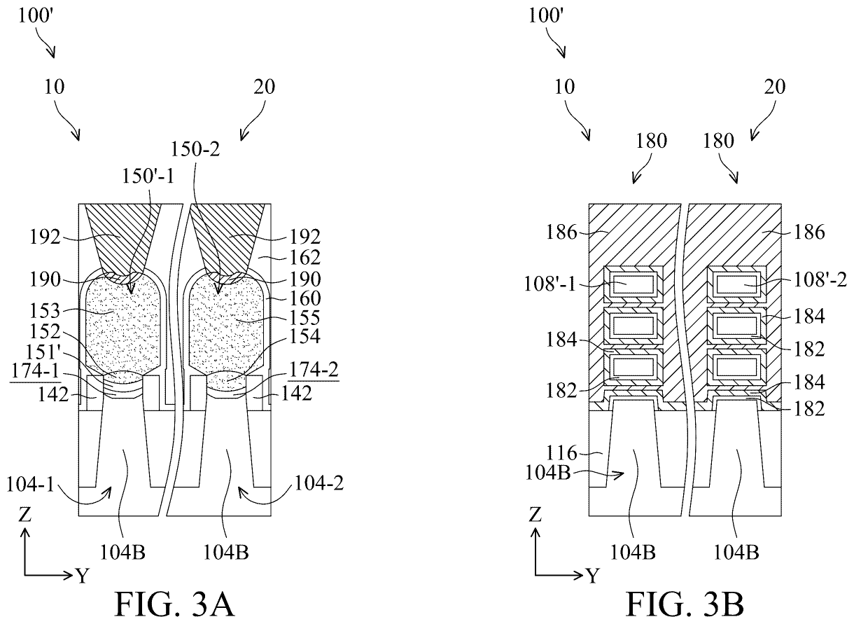

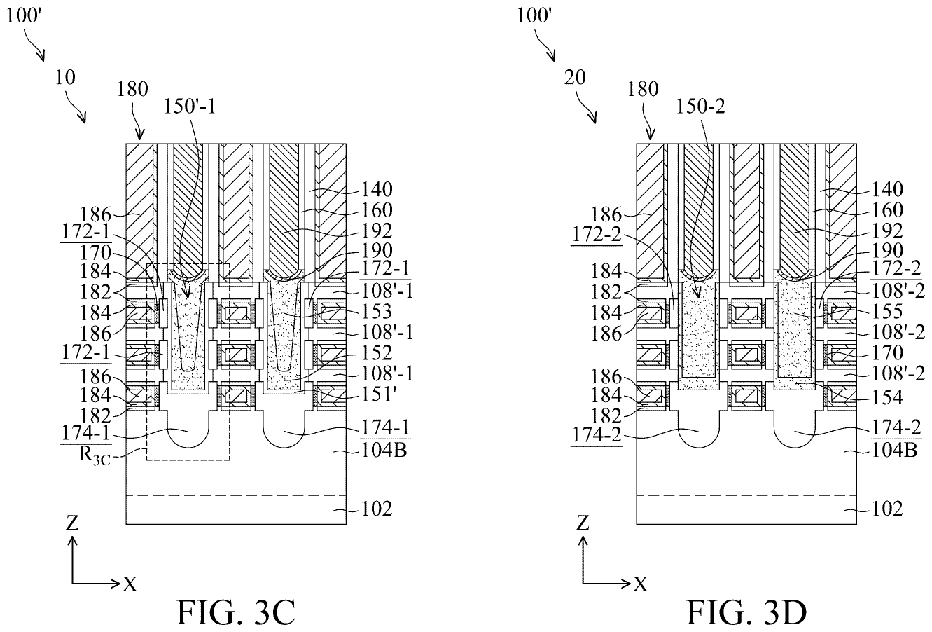

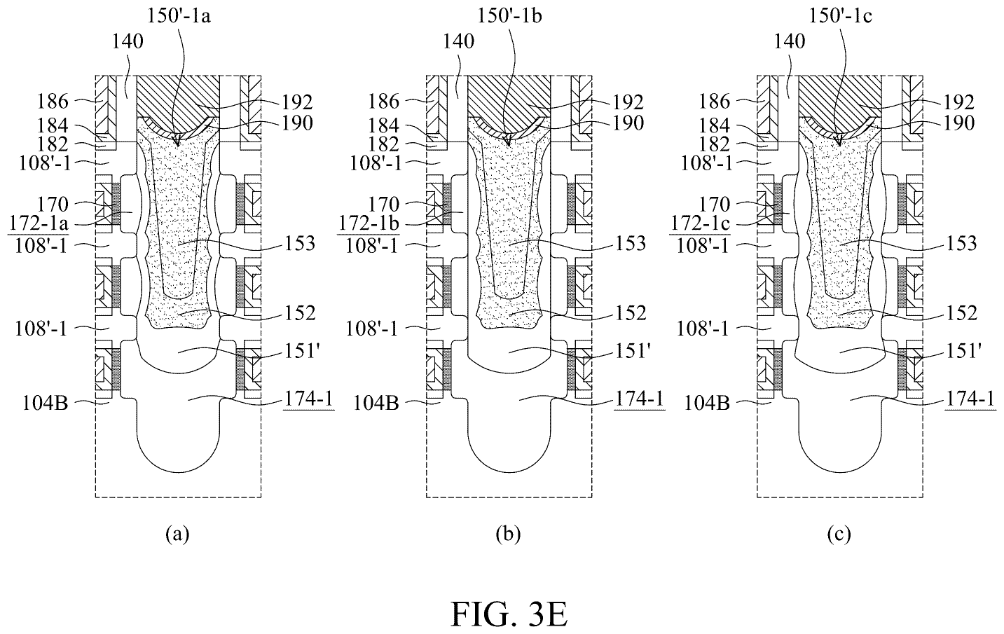

FIGS. 2G-5, 2G-6, and 2G-7 illustrate enlarged cross-sectional views of the region R_{2G-3} shown in FIG. 2G-3 in accordance with various embodiments. More specifically, FIG. 2G-5(a) illustrates the second semiconductor material layers 108 having concave sidewall surfaces vertically overlapping the sacrificial inner spacer 148a in accordance with some embodiments. FIG. 2G-5(b) illustrates the second semiconductor material layers 108 having concave sidewall surfaces vertically overlapping the sacrificial inner spacer 148b in accordance with some embodiments. FIG. 2G-5(c) illustrates the second semiconductor material layers 108 having concave sidewall surfaces vertically overlapping the sacrificial inner spacer 148c in accordance with some embodiments. FIG. 2G-6(a) illustrates the second semiconductor material layers 108 having substantially vertical sidewall surfaces vertically overlapping the sacrificial inner spacer 148a in accordance with some embodiments. FIG. 2G-6(b) illustrates the second semiconductor material layers 108 having substantially vertical sidewall surfaces vertically overlapping the sacrificial inner spacer 148b in accordance with some embodiments. FIG. 2G-6(c) illustrates the second semiconductor material layers 108 having substantially vertical sidewall surfaces vertically overlapping the sacrificial inner spacer 148c in accordance with some embodiments. FIG. 2G-7(a) illustrates the second semiconductor material layers 108 having convex sidewall surfaces vertically overlapping the sacrificial inner spacer 148a in accordance with some embodiments. FIG. 2G-7(b) illustrates the second semiconductor material layers 108 having convex sidewall surfaces vertically overlapping the sacrificial inner spacer 148b in accordance with some embodiments. FIG. 2G-7(c) illustrates the second semiconductor material layers 108 having convex sidewall surfaces vertically overlapping the sacrificial inner spacer 148c in accordance with some embodiments.

In some embodiments, the second semiconductor material layers 108 are laterally recessed for a distance D₁ in a range of about 2 nm to about 6 nm. The recessed distance D₁ should be great enough for the dopant diffusion but should not be too great or the risk of current leakage may be increased. In some embodiments, the second semiconductor material layers 108 is protruded from the inner sidewalls of the gate spacers 140 for a distance D₂ in a range from about 3 nm to about 5 nm. In some embodiments, the distance D₁ is greater than the distance D₂, as shown in FIG. 2G-5. In some embodiments, the distance D₁ is substantially equal to the distance D₂, as shown in FIG. 2G-6. In some embodiments, the distance D₁ is less than the distance D₂, as shown in FIG. 2G-7.

After the recessing process is performed, source/drain structures 150-1 and 150-2 are formed in the source/drain recesses 144 in the first region 10 and the second region 20 respectively, as shown in FIGS. 2H-1, 2H-2, 2H-3, and 2H-4 in accordance with some embodiments. The source/drain structures described herein may refer to a source or a drain, individually or collectively dependent upon the context.

In some embodiments, the source/drain structures 150-1 and 150-2 are formed using epitaxial growth processes which may be performed separately, such as MBE, MOCVD, VPE, other applicable epitaxial growth process, or a combination thereof. In some embodiments, the source/drain structures 150-1 and 150-2 are made of any applicable material, such as Ge, Si, GaAs, AlGaAs, SiGe, GaAsP, SiP, SiC, SiCP, or a combination thereof. In some embodiments, the source/drain structures 150-1 and 150-2 are in-situ doped during the epitaxial growth process. In some embodiments, the source/drain structures 150-1 and 150-2 are doped in one or more implantation processes after the epitaxial growth process.

In some embodiments, the source/drain structures 150-1 and 150-2 are made of materials with different conductivity types. FIG. 2H-5 illustrates enlarged cross-sectional views of the region R_{2H-3} shown in FIG. 2H-3 in accordance with various embodiments. More specifically, FIG. 2H-5(a) illustrates a source/drain structure 150-1a formed next to the sacrificial inner spacers 148a in accordance with some embodiments. FIG. 2H-5(b) illustrates a source/drain structure 150-1b formed next to the sacrificial inner spacers 148b in accordance with some embodiments. FIG. 2H-5(c) illustrates a source/drain structure 150-1c formed next to the sacrificial inner spacers 148c in accordance with some embodiments. It should be noted that although the bottom sacrificial layers 149c are shown in FIG. 2H-5, it may be replaced by other types of the bottom sacrificial layers, such as the bottom sacrificial layers 149a or 149b shown in FIG. 2F-6.

In some embodiments, the source/drain structure 150-1 includes a first source/drain layer 151, a second source/drain layer 152 formed over the first source/drain layer 151, and a third source/drain layer 153 formed over the second source/drain layer 152. In some embodiments, the source/drain structure 150-1 is source/drain structure for a PMOS transistor, the Ge concentration in the third source/drain layer 153 is greater than the Ge concentration in the second source/drain layer 152, and the Ge concentration in the second source/drain layer 152 is greater than the Ge concentration in the first source/drain layer 151. In some embodiments, the first source/drain layer 151 is made of SiB. In some embodiments, the second source/drain layer 152 is made of SiGeB, and the Ge concentration in the second source/drain layer 152 is greater than 0 but less than about 25%. In some embodiments, the third source/drain layer 153 is made of SiGeB, and the Ge concentration in the third source/drain layer 153 is greater than 25%.

In some embodiments, the first source/drain layer 151 is in contact with the sidewalls of the second semiconductor material layers 108, the sacrificial inner spacers 148 (e.g. 148a, 148b, or 148c), and the bottom sacrificial layer 149 (e.g. 149a, 149b, or 149c). In addition, since the second semiconductor material layers 108 are laterally recessed before the source/drain structure 150-1 is formed, the first source/drain layer 151 laterally extends over the sacrificial inner spacers 148 in accordance with some embodiments. The thickness of the first source/drain 151 at different regions are different due to the difference of the growth rate of the epitaxy material formed on different materials. Therefore, the first source/drain layer 151 has wavy sidewall surface with thicker portions next to the second semiconductor material layers 108 and thinner portions next to the sacrificial inner spacers 148 in accordance with some embodiments.

In some embodiments, the first source/drain layer 151 includes extending portion that is vertically sandwiched (i.e. in Z direction) between the gate spacer 140 and the topmost one of the second semiconductor material layers 108, between two vertically neighboring second semiconductor material layers 108, and between the bottommost one of the second semiconductor material layers 108 and the bottom sacrificial layer 149. Although the second semiconductor material layers 108 shown in FIG. 2H-5 has concave sidewall surfaces, they may have the structure shown in FIGS. 2G-6 and 2G-7. In some embodiments, the first source/drain layer 151 and the second semiconductor material layers 108 has curved interface. In some other embodiments, the first source/drain layer 151 and the second semiconductor material layers 108 has substantially vertical interface. In some embodiments, the first source/drain layer 151 has curved (convex) bottom surface. In some other embodiments, the first source/drain layer 151 has substantially flat or concave bottom surface. In some embodiments, the second source/drain layer 152 is formed over the first source/drain layer 151.

As shown in FIG. 2H-5, the source/drain structure 150-1 has a width W_{150-1W} measured from a middle portion (in Z direction) of the topmost one of the second semiconductor material layers 108 in X direction and a width W_{150-1N} measured from a middle portion (in Z direction) of the topmost one of the first semiconductor material layers 106 (or the topmost one of the sacrificial inner spacers 148) in X direction. In some embodiments, the width W_{150-1W} is greater than the width W_{150-1N}.

FIG. 2H-6 illustrates enlarged cross-sectional views of the region R_{2H-4} shown in FIG. 2H-4 in accordance with various embodiments. More specifically, FIG. 2H-6(a) illustrates a source/drain structure 150-2a formed next to the sacrificial inner spacers 148a in accordance with some embodiments. FIG. 2H-6(b) illustrates a source/drain structure 150-2b formed next to the sacrificial inner spacers 148b in accordance with some embodiments. FIG. 2H-6(c) illustrates a source/drain structure 150-2c formed next to the sacrificial inner spacers 148c in accordance with some embodiments. It should be noted that although the bottom sacrificial layer 149c is shown in FIG. 2H-6, it may be replaced by other types of the bottom sacrificial layers, such as the bottom sacrificial layers 149a or 149b shown in FIG. 2F-6.

In some embodiments, the source/drain structure 150-2 includes a first source/drain layer 154 and a second source/drain layer 155. In some embodiments, the P concentration in the second source/drain layer 155 is greater than the P concentration in the first source/drain layer 154. In some embodiments, the first source/drain layer 154 is made of SiAs or SiP. In some embodiments, the second source/drain layer 155 is made of SiP.

In some embodiments, the first source/drain layer 154 is in contact with the sidewalls of the second semiconductor material layers 108, the sacrificial inner spacers 148 (e.g. 148a, 148b, or 148c), and the bottom sacrificial layer 149 (e.g. 149a, 149b, or 149c). Although the second semiconductor material layers 108 shown in FIG. 2H-6 has concave sidewall surfaces, they may have the structure shown in FIGS. 2G-6 and 2G-7. In some embodiments, the first source/drain layer 154 and the second semiconductor material layers 108 has curved interface. In some other embodiments, the first source/drain layer 154 and the second semiconductor material layers 108 has substantially vertical interface. In some embodiments, the first source/drain layer 154 has curved (convex) bottom surface. In some other embodiments, the first source/drain layer 154 has substantially flat or concave bottom surface. In some embodiments, the second source/drain layer 155 is formed over the first source/drain layer 154.

As shown in FIG. 2H-6, the source/drain structure 150-2 has a width W_{150-2W} measured from a middle portion (in Z direction) of the topmost one of the second semiconductor material layers 108 in X direction and a width W_{150-2N} measured from a middle portion (in Z direction) of the topmost one of the first semiconductor material layers 106 (or the topmost one of the sacrificial inner spacers 148) in X direction. In some embodiments, the width W_{150-1W} of the source/drain structure 150-1 is greater than the width W_{150-2N} of the source/drain structure 150-2. In some embodiments, the width W_{150-1N} of the source/drain structure 150-1 is substantially equal to the width W_{150-2N} of the source/drain structure 150-2.

After the source/drain structures 150-1 and 150-2 are formed, a contact etch stop layer (CESL) 160 is conformally formed to cover the source/drain structures 150-1 and 150-2, and an interlayer dielectric (ILD) layer 162 is formed over the contact etch stop layers 160, as shown in FIGS. 2I-1, 2I-2, 2I-3, and 2I-4 in accordance with some embodiments.

In some embodiments, the contact etch stop layer 160 is made of a dielectric materials, such as silicon nitride, silicon oxide, silicon oxynitride, another suitable dielectric material, or a combination thereof. The dielectric material for the contact etch stop layers 160 may be conformally deposited over the semiconductor structure by performing CVD, ALD, other application methods, or a combination thereof.

The interlayer dielectric layer 162 may include multilayers made of multiple dielectric materials, such as silicon oxide, silicon nitride, silicon oxynitride, phosphosilicate glass (PSG), borophosphosilicate glass (BPSG), or other applicable low-k dielectric materials. The interlayer dielectric layer 162 may be formed by chemical vapor deposition (CVD), physical vapor deposition, (PVD), atomic layer deposition (ALD), or other applicable processes. After the contact etch stop layer 160 and the interlayer dielectric layer 162 are deposited, a planarization process such as CMP or an etch-back process is performed until the dummy gate electrode layer 134 is exposed in accordance with some embodiments.

Next, the dummy gate structure 130 and the first semiconductor material layers 106 are removed to form a gate trench 166, as shown in FIGS. 2J-1, 2J-2, 2J-3, and 2J-4 in accordance with some embodiments. More specifically, the dummy gate structure 130 and the first semiconductor material layers 106 are removed to form channel structures (e.g. nanostructures) 108′-1 and 108′-2 with the second semiconductor material layers 108 of the fin structures 104-1 and 104-2 respectively in accordance with some embodiments. As shown in FIGS. 2J-3 and 2J-4, the channel structures 108′-1 and 108′-2 are vertically suspended over the substrate 102 and spaced apart from each other in Z direction in accordance with some embodiments. In addition, the channel structures 108′-1 and 108′-2 laterally extend between and interposing the source/drain structures 150-1 and 150-2 respectively in X direction in accordance with some embodiments.

The removal process may include one or more etching processes. For example, when the dummy gate electrode layer 134 may be made of polysilicon, a wet etchant such as a tetramethylammonium hydroxide (TMAH) solution may be used to selectively remove the dummy gate electrode layer 134. Afterwards, the dummy gate dielectric layer 132 may be removed using a plasma dry etching, a dry chemical etching, and/or a wet etching. The first semiconductor material layers 106 may be removed by performing a selective wet etching process, such as an APM (e.g., ammonia hydroxide-hydrogen peroxide-water mixture) etching process. For example, the wet etching process uses etchants such as ammonium hydroxide (NH₄OH), TMAH, ethylenediamine pyrocatechol (EDP), and/or potassium hydroxide (KOH) solutions.

As described previously, although the first semiconductor material layers 106 and the sacrificial inner spacers 148 and the bottom sacrificial layers 149 are all made of SiGe, the Ge concentration of the first semiconductor material layers 106 may be higher than the Ge concentration of the sacrificial inner spacers 148 and the bottom sacrificial layers 149. Therefore, the first semiconductor material layers 106 and the sacrificial inner spacers 148 and the bottom sacrificial layers 149 may have good etching selectivity during the etching process for removing the first semiconductor material layers 106. In some embodiments, the sidewalls of the sacrificial inner spacers 148 and the bottom sacrificial layers 149 are slightly removed during the etching process for removing the first semiconductor material layers 106.

FIG. 2J-5 illustrates enlarged cross-sectional views of the region R_{2J-3} shown in FIG. 2J-3 in accordance with various embodiments. More specifically, FIG. 2J-5(a-1) illustrates a sacrificial inner spacer 148a-1 with a concave inner sidewall in the first region 10 in accordance with some embodiments. FIG. 2J-5(a-2) illustrates a sacrificial inner spacer 148a-2 with a substantially vertical inner sidewall in the first region 10 in accordance with some embodiments. FIG. 2J-5(b-1) illustrates a sacrificial inner spacer 148b-1 with a concave inner sidewall in the first region 10 in accordance with some embodiments. FIG. 2J-5(b-2) illustrates a sacrificial inner spacer 148b-2 with a substantially vertical inner sidewall in the first region 10 in accordance with some embodiments. FIG. 2J-5(c-1) illustrates a sacrificial inner spacer 148c-1 with a concave inner sidewall in the first region 10 in accordance with some embodiments. FIG. 2J-5(c-2) illustrates a sacrificial inner spacer 148c-2 with a substantially vertical inner sidewall in the first region 10 in accordance with some embodiments.

FIG. 2J-6 illustrates enlarged cross-sectional views of the region R_{2J-4} shown in FIG. 2J-4 in accordance with various embodiments. More specifically, FIG. 2J-6(a-1) illustrates the sacrificial inner spacer 148a-1 with a concave inner sidewall in the second region 20 in accordance with some embodiments. FIG. 2J-6(a-2) illustrates the sacrificial inner spacer 148a-2 with a substantially vertical inner sidewall in the second region 20 in accordance with some embodiments. FIG. 2J-6(b-1) illustrates the sacrificial inner spacer 148b-1 with a concave inner sidewall in the second region 20 in accordance with some embodiments. FIG. 2J-6(b-2) illustrates the sacrificial inner spacer 148b-2 with a substantially vertical inner sidewall in the second region 20 in accordance with some embodiments. FIG. 2J-6(c-1) illustrates the sacrificial inner spacer 148c-1 with a concave inner sidewall in the second region 20 in accordance with some embodiments. FIG. 2J-6(c-2) illustrates the sacrificial inner spacer 148c-2 with a substantially vertical inner sidewall in the second region 20 in accordance with some embodiments.

After the gate trench 166 is formed, porous layers 170 are formed over the inner sidewalls of the sacrificial inner spacers 148 in both of the first region 10 and the second region 20, as shown in FIGS. 2K-1, 2K-2, 2K-3, and 2K-4 in accordance with some embodiments. The porous layers 170 are configured to secure the spaces between the gate structure and the source/drain structures 150-1 and 150-2.

In some embodiments, the porous layers 170 are made of SiO₂. In some embodiments, the porous layer 170 has a thickness in a range from about 0.5 nm to about 2 nm, measured in X direction. The porous layers 170 should be thick enough, or they may be removed during the etching process performed afterwards. On the other hand, the porous layers 170 should not be too thick, or the sacrificial inner spacers 148 and the bottom sacrificial layers 149 may not be completely removed (the details will be described afterwards.) In some embodiments, the porous layers 170 are formed by performing a wet process. In some embodiments, the wet process includes spraying a reactant liquid to the sidewall surfaces of the sacrificial inner spacers 148 and the bottom sacrificial layers 149 exposed by the gate trench 166 to form the porous layers 170 and removing the reactant liquid after the porous layers 170 are formed. In some embodiments, the porous layers 170 have curved profile in the cross-sectional view.

FIG. 2K-5 illustrates enlarged cross-sectional views of the region R_{2K-3} shown in FIG. 2K-3 in accordance with various embodiments. More specifically, FIG. 2K-5(a-1) illustrates a porous layer 170a-1 formed on the concave inner sidewall of the sacrificial inner spacer 148a-1 in the first region 10 in accordance with some embodiments. FIG. 2K-5(a-2) illustrates a porous layer 170a-2 formed on the substantially vertical inner sidewall of the sacrificial inner spacer 148a-2 in the first region 10 in accordance with some embodiments. FIG. 2K-5(b-1) illustrates a porous layer 170b-1 formed on the concave inner sidewall of the sacrificial inner spacer 148b-1 in the first region 10 in accordance with some embodiments. FIG. 2K-5(b-2) illustrates a porous layer 170b-2 formed on the substantially vertical inner sidewall of the sacrificial inner spacer 148b-2 in the first region 10 in accordance with some embodiments. FIG. 2K-5(c-1) illustrates a porous layer 170c-1 formed on the concave inner sidewall of the sacrificial inner spacer 148c-1 in the first region 10 in accordance with some embodiments. FIG. 2K-5(c-2) illustrates a porous layer 170c-2 formed on the substantially vertical inner sidewall of the sacrificial inner spacer 148c-2 in the first region 10 in accordance with some embodiments.

FIG. 2K-6 illustrates enlarged cross-sectional views of the region R_{2K-4} shown in FIG. 2K-4 in accordance with various embodiments. More specifically, FIG. 2K-6(a-1) illustrates the porous layer 170a-1 formed on the concave inner sidewall of the sacrificial inner spacer 148a-1 in the second region 20 in accordance with some embodiments. FIG. 2K-6(a-2) illustrates the porous layer 170a-2 formed on the substantially vertical inner sidewall of the sacrificial inner spacer 148a-2 in the second region 20 in accordance with some embodiments. FIG. 2K-6(b-1) illustrates the porous layer 170b-1 formed on the concave inner sidewall of the sacrificial inner spacer 148b-1 in the second region 20 in accordance with some embodiments. FIG. 2K-6(b-2) illustrates the porous layer 170b-2 formed on the substantially vertical inner sidewall of the sacrificial inner spacer 148b-2 in the second region 20 in accordance with some embodiments. FIG. 2K-6(c-1) illustrates the porous layer 170c-1 formed on the concave inner sidewall of the sacrificial inner spacer 148c-1 in the second region 20 in accordance with some embodiments. FIG. 2K-6(c-2) illustrates the porous layer 170c-2 formed on the substantially vertical inner sidewall of the sacrificial inner spacer 148c-2 in the second region 20 in accordance with some embodiments.

After the porous layers 170 are formed, an etching process is performed from the gate trench 166 to remove the sacrificial inner spacers 148 and the bottom sacrificial layers 149, as shown in FIGS. 2L-1, 2L-2, 2L-3, and 2L-4 in accordance with some embodiments. More specifically, during the etching process, an etchant penetrate through pores in the porous layers 170 and reach the sacrificial inner spacers 148 and the bottom sacrificial layers 149 in accordance with some embodiments. Then, the sacrificial inner spacers 148 and the bottom sacrificial layers 149 are etched by the etchant and removed with the etchant, so that air gaps 172-1 and 172-2 and bottom air gaps 174-1 and 174-2 are formed in the first region 10 and the second region 20, respectively, in accordance with some embodiments.

In some embodiments, the etching process is a dry etching process. In some embodiments, the etchant used in the etching process includes fluorine radical, hydrogen radical, or the like. As described previously, the source/drain structures 150-1 include the first source/drain layers 151, which may be made of SiB, and the first source/drain layers 151 may be used as protection layers of the source/drain structures 150-1, so that the second source/drain layers 152 (which may be made of SiGeB) will not be damaged during the etching process.

In some embodiments, the air gaps 172-1 and 172-2 are formed by removing the sacrificial inner spacers 148, and the bottom air gaps 174-1 and 174-2 are formed by removing the bottom sacrificial layers 149. Accordingly, the air gaps 172-1 are laterally sandwiched (i.e. in X direction) between the porous layers 170 and the first source/drain layer 151 in the first region 10, and the air gaps 172-2 are laterally sandwiched (i.e. in X direction) between the porous layers 170 and the first source/drain layer 154 in the second region 20 in accordance with some embodiments. In addition, the bottom air gaps 174-1 and 174-2 are vertically sandwiched (i.e. in Z direction) between the base fin structure 104B and the source/drain structures 150-1 and 150-2 in accordance with some embodiments. Furthermore, the bottom air gaps 174-1 and 174-2 are laterally sandwiched (i.e. in X direction) between two porous layers 170 in accordance with some embodiments.

FIG. 2L-5 illustrates enlarged cross-sectional views of the region R_{2L-3} shown in FIG. 2L-3 in accordance with various embodiments. More specifically, FIG. 2L-5(a-1) illustrates an air gap 172-1a1 exposing the porous layer 170a-1 and has the shape substantially the same as the sacrificial inner spacer 148a-1 in the first region 10 in accordance with some embodiments. FIG. 2L-5(a-2) illustrates an air gap 172-1a2 exposing the porous layer 170a-2 and has the shape substantially the same as the sacrificial inner spacer 148a-2 in the first region 10 in accordance with some embodiments. FIG. 2L-5(b-1) illustrates an air gap 172-1b1 exposing the porous layer 170b-1 and has the shape substantially the same as the sacrificial inner spacer 148b-1 in the first region 10 in accordance with some embodiments. FIG. 2L-5(b-2) illustrates an air gap 172-1b2 exposing the porous layer 170b-2 and has the shape substantially the same as the sacrificial inner spacer 148b-2 in the first region 10 in accordance with some embodiments. FIG. 2L-5(c-1) illustrates an air gap 172-1c1 exposing the porous layer 170c-1 and has the shape substantially the same as the sacrificial inner spacer 148c-1 in the first region 10 in accordance with some embodiments. FIG. 2L-5(c-2) illustrates an air gap 172-1c2 exposing the porous layer 170c-2 and has the shape substantially the same as the sacrificial inner spacer 148c-2 in the first region 10 in accordance with some embodiments.

FIG. 2L-6 illustrates enlarged cross-sectional views of the region R_{2L-4} shown in FIG. 2L-4 in accordance with various embodiments. More specifically, FIG. 2L-6(a-1) illustrates an air gap 172-2a1 exposing the porous layer 170a-1 and has the shape substantially the same as the sacrificial inner spacer 148a-1 in the second region 20 in accordance with some embodiments. FIG. 2L-6(a-2) illustrates an air gap 172-2a2 exposing the porous layer 170a-2 and has the shape substantially the same as the sacrificial inner spacer 148a-2 in the second region 20 in accordance with some embodiments. FIG. 2L-6(b-1) illustrates an air gap 172-2b1 exposing the porous layer 170b-1 and has the shape substantially the same as the sacrificial inner spacer 148b-1 in the second region 20 in accordance with some embodiments. FIG. 2L-6(b-2) illustrates an air gap 172-2b2 exposing the porous layer 170b-2 and has the shape substantially the same as the sacrificial inner spacer 148b-2 in the second region 20 in accordance with some embodiments. FIG. 2K-6(c-1) illustrates an air gap 172-2cl exposing the porous layer 170c-1 and has the shape substantially the same as the sacrificial inner spacer 148c-1 in the second region 20 in accordance with some embodiments. FIG. 2L-6(c-2) illustrates an air gap 172-2c2 exposing the porous layer 170c-2 and has the shape substantially the same as the sacrificial inner spacer 148c-2 in the second region 20 in accordance with some embodiments.

After the air gaps 172-1 and 172-2 and the bottom air gaps 174-1 and 174-2 are formed, a gate structure 180 is formed in the gate trench 166, as shown in FIGS. 2M-1, 2M-2, 2M-3, and 2M-4 in accordance with some embodiments. In some embodiments, the gate structure 180 wraps around the channel structure 108′-1 and 108′2 in the first region 10 and the second region 20 and extends lengthwise in Y direction. In some embodiments, the gate structure 180 includes an interfacial layer 182, a gate dielectric layer 184, and a gate stack layer 186.

The interfacial layer 182 may be used to improve the interfaces between the channel structures 108′-1 and 108′-2 and dielectric layers formed afterwards. In addition, the interfacial layer 182 may be able to help suppressing the mobility degradation of charge carries in the channel structures 108′-1 and 108′-2 that serve as channel regions of the transistors. In some embodiments, the interfacial layer 182 is an oxide layer formed by performing a thermal process. In some embodiments, the interfacial layer 182 has a thickness in a range from about 0.5 nm to about 1.5 nm.

After the interfacial layer 182 is formed, the gate dielectric layer 184 is conformally formed to cover the interfacial layers 182 and the bottom surface and the sidewalls of the gate trench 166 in accordance with some embodiments. In some embodiments, the gate dielectric layer 184 is made of a dielectric material, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, La₂O₃—Al₂O₃ or LaO, other applicable high-k dielectric materials, or a combination thereof. In some embodiments, the gate dielectric layer 184 is formed using CVD, ALD, other applicable methods, or a combination thereof. In some embodiments, the gate dielectric layer 184 has a thickness in a range from about 1 nm to about 2 nm.

After the gate dielectric layer 184 is formed, the gate stack layer 186 is formed over the gate dielectric layer 184 in accordance with some embodiments. In some embodiments, the gate stack layer 186 includes multiple layers. In some embodiments, the gate stack layer 186 includes a work function metal layer. In some embodiments, the work function layers in the first region 10 and the second region 20 are made of different materials. In some embodiments, the work function metal layer is made of titanium nitride, tantalum nitride, tungsten nitride, tantalum, or the like.

In some embodiments, the gate stack layer 186 includes a gate filling layer formed over the work functional layer. In some embodiments, the gate filling layer is made of a conductive material, such as tungsten, titanium, tantalum, cobalt, copper, or the like. In some embodiments, the gate filling layer is formed using CVD, ALD, electroplating, another applicable method, or a combination thereof. In some embodiments, a polishing process, such as a CMP process, is performed after depositing the gate dielectric layer 184 and the gate stack layer 186.

FIG. 2M-5 illustrates enlarged cross-sectional views of the region R_{2M-3} shown in FIG. 2M-3 in accordance with various embodiments. More specifically, FIG. 2M-5(a-1) illustrates the air gap 172-1a1 and the gate structure 180 at opposite sides of the porous layer 170a-1 in the first region 10 in accordance with some embodiments. FIG. 2M-5(a-2) illustrates the air gap 172-1a2 and the gate structure 180 at opposite sides of the porous layer 170a-2 in the first region 10 in accordance with some embodiments. FIG. 2M-5(b-1) illustrates the air gap 172-1b1 and the gate structure 180 at opposite sides of the porous layer 170b-1 in the first region 10 in accordance with some embodiments. FIG. 2M-5(b-2) illustrates the air gap 172-1b2 and the gate structure 180 at opposite sides of the porous layer 170b-2 in the first region 10 in accordance with some embodiments. FIG. 2M-5(c-1) illustrates the air gap 172-1cl and the gate structure 180 at opposite sides of the porous layer 170c-1 in the first region 10 in accordance with some embodiments. FIG. 2M-5(c-2) illustrates the air gap 172-1c2 and the gate structure 180 at opposite sides of the porous layer 170c-2 in the first region 10 in accordance with some embodiments.

FIG. 2M-6 illustrates enlarged cross-sectional views of the region R_{2M-4} shown in FIG. 2M-4 in accordance with various embodiments. More specifically, FIG. 2M-6(a-1) illustrates the air gap 172-2a1 and the gate structure 180 at opposite sides of the porous layer 170a-1 in the second region 20 in accordance with some embodiments. FIG. 2M-6(a-2) illustrates the air gap 172-2a2 and the gate structure 180 at opposite sides of the porous layer 170a-2 in the second region 20 in accordance with some embodiments. FIG. 2M-6(b-1) illustrates the air gap 172-2b1 and the gate structure 180 at opposite sides of the porous layer 170b-1 in the second region 20 in accordance with some embodiments. FIG. 2M-6(b-2) illustrates the air gap 172-2b2 and the gate structure 180 at opposite sides of the porous layer 170b-2 in the second region 20 in accordance with some embodiments. FIG. 2M-6(c-1) illustrates the air gap 172-2cl and the gate structure 180 at opposite sides of the porous layer 170c-1 in the second region 20 in accordance with some embodiments. FIG. 2M-6(c-2) illustrates the air gap 172-2c2 and the gate structure 180 at opposite sides of the porous layer 170c-2 in the second region 20 in accordance with some embodiments.

After the gate structure 180 is formed, silicide layers 190 and source/drain contacts 192 are formed over the source/drain structures 150-1 and 150-2, as shown in FIGS. 2M-1, 2M-3, and 2M-4 in accordance with some embodiments. More specifically, contact trenches may be formed through the contact etch stop layer 160 and the interlayer dielectric layer 162 to expose the source/drain structures 150-1 and 150-2. Afterwards, the silicide layers 190 are formed over the exposed portions of the source/drain structures 150-1 and 150-2, and the source/drain contacts 192 are formed in the contact trenches over the silicide layers 190 in accordance with some embodiments.

The silicide layers 190 may be formed by forming a metal layer over the top surface of the source/drain structures 150-1 and 150-2 and annealing the metal layer so the metal layer reacts with the source/drain structures 150-1 and 150-2 to form the silicide layers 190. The unreacted metal layer may be removed after the silicide layers 190 are formed.

In some embodiments, the source/drain contacts 192 are made of a conductive material including aluminum (Al), copper (Cu), tungsten (W), titanium (Ti), tantalum (Ta), titanium nitride (TiN), cobalt, tantalum nitride (TaN), nickel silicide (NiS), cobalt silicide (CoSi), copper silicide, tantalum carbide (TaC), tantalum silicide nitride (TaSiN), tantalum carbide nitride (TaCN), titanium aluminide (TiAl), titanium aluminum nitride (TiAlN), other applicable conductive materials, or a combination thereof.

The source/drain contacts 192 may further include a liner and/or a barrier layer. For example, a liner (not shown) may be formed on the sidewalls and bottom of the contact trench. The liner may be made of silicon nitride, although any other applicable dielectric may be used as an alternative. The liner may be formed using a plasma enhanced chemical vapor deposition (PECVD) process, although other applicable processes, such as physical vapor deposition or a thermal process, may be used as an alternative. The barrier layer (not shown) may be formed over the liner (if present) and may cover the sidewalls and bottom of the opening. The barrier layer may be formed using a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition processes. The barrier layer may be made of tantalum nitride, although other materials, such as tantalum, titanium, titanium nitride, or the like, may also be used.

FIG. 2M-7 illustrates enlarged cross-sectional views of the region R_{2M-3W} shown in FIG. 2M-3 in accordance with various embodiments. More specifically, FIG. 2M-7(a) illustrates the source/drain structure 150-1a with four air gaps 172-1a partially exposing portions of its sidewall and with the bottom air gap 174-1 exposing its bottom portion in the first region 10 in accordance with some embodiments. FIG. 2M-7(b) illustrates the source/drain structure 150-1b with four air gaps 172-1b partially exposing portions of its sidewall and with the bottom air gap 174-1 exposing its bottom portion in the first region 10 in accordance with some embodiments. FIG. 2M-7(c) illustrates the source/drain structure 150-1c with four air gaps 172-1c partially exposing portions of its sidewall and with the bottom air gap 174-1 exposing its bottom portion in the first region 10 in accordance with some embodiments.

FIG. 2M-8 illustrates enlarged cross-sectional views of the region R_{2M-4W} shown in FIG. 2M-4 in accordance with various embodiments. More specifically, FIG. 2M-8(a) illustrates the source/drain structure 150-2a with four air gaps 172-2a partially exposing portions of its sidewall and with the bottom air gap 174-2 exposing its bottom portion in the second region 20 in accordance with some embodiments. FIG. 2M-8(b) illustrates the source/drain structure 150-2b with four air gaps 172-1b partially exposing portions of its sidewall and with the bottom air gap 174-2 exposing its bottom portion in the second region 20 in accordance with some embodiments. FIG. 2M-8(c) illustrates the source/drain structure 150-2c with four air gaps 172-2c partially exposing portions of its sidewall and with the bottom air gap 174-2 exposing its bottom portion in the second region 20 in accordance with some embodiments.

In some embodiments, the width of the air gaps 172-1 and 172-2 is in a range from about 3 nm to about 8 nm. The air gaps 172-1 and 172-2 should be wide enough to separate the gate structure 180 and the source/drain structures 150-1 and 150-2. On the other hand, the air gaps 172-1 and 172-2 should not be too wide, or the spaces for forming the gate structure 180 may be reduced. In some embodiments, the width of the air gaps 172-1 and 172-2 is smaller than the width of the gate spacers 140 in X direction.

In some embodiments, the width of the portion of the first source/drain layer 151 laterally sandwiched between the air gap 172-1 and the second source/drain layer 152 is in a range from about 2 nm to about 3 nm. As described previously, the first source/drain layer 151 is formed to prevent the source/drain structure 150-1 being damaged during the etching process for removing the sacrificial inner spacers 148 and the bottom sacrificial layers 149. Therefore, the portion of the first source/drain layer 151 between the air gap 172-1 and the second source/drain layer 152 should not be too thin, or the risk for the source/drain damage may be increased. In some embodiments, the first source/drain layer 151 has wavy profile in contact with the second source/drain layer 152.

In some embodiments, the width of the portion of the first source/drain layer 154 laterally sandwiched between the air gap 172-2 and the second source/drain layer 155 is in a range from about 3 nm to about 4 nm. In some embodiments, the first source/drain layer 154 has wavy profile in contact with the second source/drain layer 155. In some embodiments, the width of the portion of the first source/drain layer 154 laterally sandwiched between the air gap 172-2 and the second source/drain layer 155 is greater than the width of the portion of the first source/drain layer 151 laterally sandwiched between the air gap 172-1 and the second source/drain layer 152.

In some embodiments, the bottom air gap 174-1 has a height H₁ (in Z direction) under the middle portion (in X direction) of the source/drain structure 150-1, and the bottom air gap 174-2 has a height H₂ (in Z direction) under the middle portion (in X direction) of the source/drain structure 150-2. The height H₁ may be defined as the distance between the bottommost point of the source/drain structure 150-1 and the bottommost point of the bottom air gap 174-1 measured in Z direction. The height H₂ may be defined as the distance between the bottommost point of the source/drain structure 150-2 and the bottommost point of the bottom air gap 174-2 measured in Z direction. In some embodiments, the height H₁ is substantially equal to the height H₂.

Since the bottom portions of the source/drain structures 150-1 and 150-2 are lower than the topmost surface of the bottom air gaps 174-1 and 174-2, there are necking regions, which has the narrowest distance between the source/drain structures 150-1/150-2 and base fin structure 104B, in the bottom air gaps 174-1 and 174-2. In some embodiments, the dimension D_{N} of the necking region in both the bottom air gaps 174-1 and 174-2 is greater than about 2 nm. The necking region should be large enough so the bottom sacrificial layers 149 can be completely removed in the etching process shown in FIGS. 2L-1 to 2L-4.

As shown in FIGS. 2M-1 to 2M-8, the semiconductor structure 100 includes channel structures 108′-1/108′-2 vertically separated from each other and the gate structure 180 wrapping around the channel structures in accordance with some embodiments. In addition, the porous layers 170 are formed over the sidewalls of the gate structure 180 under the channel structures 108′-1/108′-2 in accordance with some embodiments. Furthermore, the source/drain structures 150-1/150-2 attached to the channel structures 108′-1/108′-2, and the source/drain structures 150-1/150-2 are laterally separated from the porous layers by the air gaps 172. In some embodiments, the porous layers 170 and the gate structure 180 have curved interfaces. In some embodiments, the bottommost one of the porous layers 170 connects the bottommost one of the channel structures 108′-1/108′-2 and the top surface of the base fin structure 104B.

In some embodiments, the bottom surfaces of the source/drain structures 150-1/150-2 and the bottom surface of the bottommost one of the channel layers 108′-1/108′-2 are exposed by the bottom air gaps 174-1/174-2. In some embodiments, the bottom air gap 174 is wider than the air gap 172. In some embodiments, the bottom air gaps 174-1/174-2 overlap the gate spacers 140 in Z direction. In some embodiments, the dimension of the bottom air gap 174-1/174-2 is greater than the dimension of the source/drain structure 150-1/150-2 in X direction.

In some embodiments, the source/drain structure 150-1 has laterally extending portions in contact with the channel structures 108′-1, and bottom surfaces of the extending portions of the source/drain structure 150-1 are exposed by the air gaps 172. In some embodiments, the source/drain structure 150-1 has a first portion in contact with the sidewall surface of the bottommost one of the channel structures 108′-1 and a second portion over the first portion, and the first portion is wider than the second portion in X direction. In some embodiments, the gate spacers 140 are formed over the topmost one of the channel structures 108′-1, and an extending portion of the source/drain structure 150-1 is in contact with a bottom surface of the gate spacer.

FIGS. 3A, 3B, 3C, and 3D illustrate cross-sectional views of a semiconductor structure 100′ in accordance with some embodiments. The semiconductor structure 100′ may be similar to the semiconductor structure 100 described previously, except the second semiconductor material layers 108 in the first region 10 are not recessed before forming the source/drain structures 150-1 in accordance with some embodiments. Processes and materials for forming the semiconductor structure 100′ may be similar to, or the same as, those for forming the semiconductor structure 100 described previously and are not repeated herein.

More specifically, the processes shown in FIGS. 2A-1 to 2F-1, 2A-2 to 2F-2, 2A-3 to 2F-3, and 2A-4 to 2F-4 are performed to form sacrificial inner spacers 148 and the bottom sacrificial layers 149, and then the processes shown in FIGS. 2H-1 to 2M-1, 2H-2 to 2M-2, 2H-3 to 2M-3, and 2H-4 to 2M-4 are performed to form the semiconductor structure 100′, as shown in FIGS. 3A, 3B, 3C, and 3E in accordance with some embodiments. Since the recessing process shown in FIGS. 2G-1 to 2G-4 are not performed, the sidewalls of the channel structures 108′-1 and 108′-2 are both substantially aligned with the sidewall of the gate spacers 140 in accordance with some embodiments.

In some embodiments, a source/drain structure 150′-1 is formed in the semiconductor structure 100′. In addition, the source/drain structure 150′-1 include a first source/drain layer 151′, the second source/drain layer 152, and the third source/drain layer 153. The source/drain layer 151′ is the same as the source/drain layer 151, except the source/drain layer 151′ does not extend under the gate spacers 140.

FIG. 3E illustrates enlarged cross-sectional views of the region R_{3C} shown in FIG. 3C in accordance with various embodiments. More specifically, FIG. 3E(a) illustrates the source/drain structure 150′-1a with four air gaps 172-1a partially exposing portions of its sidewall of the first source/drain layer 151′ and with the bottom air gap 174-1 exposing its bottom portion of the first source/drain layer 151′ in the first region 10 in accordance with some embodiments. FIG. 3E(b) illustrates the source/drain structure 150′-1b with four air gaps 172-1b partially exposing portions of its sidewall of the first source/drain layer 151′ and with the bottom air gap 174-1 exposing its bottom portion of the first source/drain layer 151′ in the first region 10 in accordance with some embodiments. FIG. 3E(c) illustrates the source/drain structure 150-1c with four air gaps 172-1c partially exposing portions of its sidewall of the first source/drain layer 151′ and with the bottom air gap 174-1 exposing its bottom portion of the first source/drain layer 151′ in the first region 10 in accordance with some embodiments.

Generally, inner spacers may be formed to separate the gate structure and the source/drain structures and to provide low capacitance for electrical properties. In accordance with the embodiments of the application, the air gaps 172 and the bottom air gaps 174 with low K value are formed as the inner spacers. The formation of the air gaps 172 and the bottom air gaps 174 may help to improve the capacitance of the resulting devices and may prevent current leakage from the bottom of the devices.

In addition, before forming the air gaps 172 and the bottom air gaps 174, the sacrificial inner spacers 148 and the bottom sacrificial layers 149 are formed, and the source/drain structures 150-1 and 150-2 are formed between and over the sacrificial inner spacers 148 and the bottom sacrificial layers 149 in accordance with some embodiments. Since the sacrificial inner spacers 148 and the bottom sacrificial layers 149 are formed by the semiconductor material, such as SiGe, the source/drain structures 150-1 and 150-2 formed thereon may have more smoothly profiles.

It should be appreciated that the elements shown in the semiconductor structures 100 and 100′ may be combined and/or exchanged. In addition, it should be noted that same elements in FIGS. 1A to 3E may be designated by the same numerals and may include materials that are the same or similar and may be formed by processes that are the same or similar; therefore such redundant details are omitted in the interests of brevity. In addition, although FIGS. 1A to 3E are described in relation to the method, it will be appreciated that the structures disclosed in FIGS. 1A to 3E are not limited to the method but may stand alone as structures independent of the method. Similarly, the methods shown in FIGS. 1A to 3E are not limited to the disclosed structures but may stand alone independent of the structures. Furthermore, the channel structures (e.g. the nanostructures) described above may include nanowires, nanosheets, or other applicable nanostructures in accordance with some embodiments.

Also, while the disclosed methods are illustrated and described above as a series of acts or events, it should be appreciated that the illustrated ordering of such acts or events may be altered in some other embodiments. For example, some acts may occur in a different order and/or concurrently with other acts or events apart from those illustrated and/or described above. In addition, not all illustrated acts may be required to implement one or more aspects or embodiments of the description above. Furthermore, one or more of the acts depicted above may be carried out as one or more separate acts and/or phases.

Furthermore, the terms “approximately,” “substantially,” “substantial” and “about” used above account for small variations and may be varied in different technologies and be within the deviation range understood by the skilled in the art. For example, when used in conjunction with an event or circumstance, the terms can refer to instances in which the event or circumstance occurs precisely as well as instances in which the event or circumstance occurs in a close approximation.

Embodiments for forming semiconductor structures may be provided. The semiconductor structure may include forming a gate dielectric layer in a first region and a second region and modifying the gate dielectric layer with a first metal element in the first region but not in the second region. Afterwards, a cap layer may be formed over the modified gate dielectric layer to densify the gate dielectric layer, so the quality of the gate dielectric layer may be improved. Next, a work function metal layer may be formed in both the first region and the second region. Since the gate dielectric layer in the first region is doped with the first metal element, the threshold voltages of the first and second transistor may be different.

Semiconductor structures and method for forming the same are provided. The semiconductor structure includes channel structures vertically separated from each other and a gate structure wrapping around the channel structures. The semiconductor structure further includes a first porous layer formed over a first sidewall of the gate structure under the channel structures and a source/drain structure attached to the channel structures. In addition, the source/drain structure is laterally separated from the first porous layer by a first air gap.

Semiconductor structures and method for forming the same are provided. The semiconductor structure includes a base fin structure protruding from a substrate and channel structures formed over the base fin structure. The semiconductor structure further includes a source/drain structure attached to the channel structures in a first direction and a gate structure wrapping around the channel structures and longitudinally oriented along a second direction different from the first direction. The semiconductor structure further includes porous layers covering sidewalls of the gate structure. In addition, a bottommost one of the porous layers connects a bottommost one of the channel structures and a top surface of the base fin structure. Furthermore, a bottom surface of the source/drain structure and a bottom surface of a bottommost one of the channel layer is exposed by a bottom air gap.

Semiconductor structures and method for forming the same are provided. The method for forming the semiconductor structure includes alternately stacking first semiconductor material layers and second semiconductor material layers in a first direction to form a semiconductor stack over a substrate and patterning the semiconductor stack to form a fin structure longitudinally oriented along a second direction being orthogonal to the first direction. The method further includes forming a source/drain trench in the fin structure and recessing the first semiconductor material layers to form notches. The method further includes forming sacrificial inner spacers in the notches and a sacrificial bottom layer in a bottom region of the source/drain trench and forming a source/drain structure over the sacrificial bottom layer. The method further includes removing the first semiconductor material layers to form a gate trench and forming porous layers on sidewalls of the sacrificial inner spacers and a sidewall of the sacrificial bottom layer. The method further includes removing the sacrificial inner spacers and the sacrificial bottom layer and forming a gate structure in the gate trench.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
channel structures vertically separated from each other;
a gate structure wrapping around the channel structures;
a first porous layer formed over a first sidewall of the gate structure under the channel structures; and
a source/drain structure attached to the channel structures, wherein the source/drain structure is laterally separated from the first porous layer by a first air gap.

2. The semiconductor structure as claimed in claim 1, wherein a bottom surface of the source/drain structure is exposed by the first air gap.

3. The semiconductor structure as claimed in claim 1, further comprising:
a second porous layer covering a second sidewall of the gate structure and in contact with a bottom surface of a topmost one of the channel structures, wherein the source/drain structure is laterally separated from the second porous layer by a second air gap.

4. The semiconductor structure as claimed in claim 3, wherein the first air gap is wider than the second air gap.

5. The semiconductor structure as claimed in claim 1, wherein the source/drain structure has a laterally extending portion in contact with the channel structures, and a bottom surface of the lateral extending portion of the source/drain structure is exposed by the first air gap.

6. The semiconductor structure as claimed in claim 1, wherein the first porous layer comprises SiO₂.

7. The semiconductor structure as claimed in claim 1, wherein the first porous layer has a curved profile in a cross-sectional view.

8. A semiconductor structure, comprising:
a base fin structure protruding from a substrate;
channel structures formed over the base fin structure;
a source/drain structure attached to the channel structures in a first direction; and
a gate structure wrapping around the channel structures and longitudinally oriented along a second direction different from the first direction,
wherein a bottom surface of the source/drain structure and a bottom surface of a bottommost one of the channel structures is exposed by a bottom air gap.

9. The semiconductor structure as claimed in claim 8, further comprising:
porous layers covering sidewalls of the gate structure, wherein a bottommost one of the porous layers connects a bottommost one of the channel structures and a top surface of the base fin structure, and the source/drain structure is separated from the porous layers by air gaps in the first direction.

10. The semiconductor structure as claimed in claim 8, further comprising:
a gate spacer formed over a topmost one of the channel structures, wherein an extending portion of the source/drain structure is in contact with a bottom surface of the gate spacer.

11. The semiconductor structure as claimed in claim 10, wherein the bottom air gap overlaps the gate spacer in a third direction different from the first direction and the second direction.

12. The semiconductor structure as claimed in claim 8, wherein a dimension of the bottom air gap is greater than a dimension of the source/drain structure in the first direction.

13. The semiconductor structure as claimed in claim 8, wherein the source/drain structure has a first portion in contact with a sidewall surface of the bottommost one of the channel structures and a second portion over the first portion, and the first portion is wider than the second portion in the first direction.

14. A method for manufacturing a semiconductor structure, comprising:
alternately stacking first semiconductor material layers and second semiconductor material layers in a first direction to form a semiconductor stack over a substrate;
patterning the semiconductor stack to form a fin structure longitudinally oriented along a second direction being orthogonal to the first direction;
forming a source/drain trench in the fin structure;
recessing the first semiconductor material layers to form notches;
forming sacrificial inner spacers in the notches and a sacrificial bottom layer in a bottom region of the source/drain trench;
forming a source/drain structure over the sacrificial bottom layer;
removing the first semiconductor material layers to form a gate trench;
forming porous layers on sidewalls of the sacrificial inner spacers and a sidewall of the sacrificial bottom layer;
removing the sacrificial inner spacers and the sacrificial bottom layer; and
forming a gate structure in the gate trench.

15. The method for manufacturing the semiconductor structure as claimed in claim 14, further comprising:
applying an etchant from the gate trench to remove the sacrificial inner spacers and the sacrificial bottom layer through the porous layers.

16. The method for manufacturing the semiconductor structure as claimed in claim 14, further comprising:
recessing the second semiconductor material layers after forming the sacrificial inner spacers in the notches.

17. The method for manufacturing the semiconductor structure as claimed in claim 16, wherein the source/drain structure partially covers the sacrificial inner spacers in the first direction.

18. The method for manufacturing the semiconductor structure as claimed in claim 14, wherein a bottom air gap is formed by removing the sacrificial bottom layer, and a bottom surface of the source/drain structure is exposed by the bottom air gap.

19. The method for manufacturing the semiconductor structure as claimed in claim 14, wherein air gaps are formed by removing the sacrificial inner spacers, and the source/drain structure is separated from the porous layers by the air gaps.

20. The method for manufacturing the semiconductor structure as claimed in claim 14, wherein the porous layers and the gate structure have curved interfaces.
